(19) United States
(12) Patent Application Publication
(10) Pub. No.: US 2007/0278666 A1
(43) Pub. Date: Dec. 6, 2007

(54) Method for Production of Electronic and Optoelectronic Circuits

(76) Inventors: Jean-Charles Garcia, Toulouse (FR); Regis Hamelin, Lyon (FR); Stephane Bernabe, Voiron (FR); Cyrille Rossat, Grenoble (FR)

Correspondence Address: YOUNG & THOMPSON, 745 SOUTH 23RD STREET, 2ND FLOOR, ARLINGTON, VA, 22202, US

(21) Appl. No.: 11/578,304

(22) PCT Filed: Apr. 12, 2005
(86) PCT No.: PCT/FR05/00881

§ 371 Date: Jul. 31, 2007

(30) Foreign Application Priority Data
Apr. 13, 2004 (FR) 0403837
Oct. 5, 2004 (FR) 0410464
Dec. 21, 2004 (FR) 0413629
Mar. 14, 2005 (FR) 0502461
Mar. 31, 2005 (FR) 0503108

(51) Int. Cl. H01L 23/10; H01L 21/02

(52) U.S. Cl. 257/707; 438/126; 257/E23.181; 257/E21.52

(57) ABSTRACT

According to the invention, in an assembly comprising an electronic component (108), said component is connected by microbeads (107) to at least one heat sink (106, 109), said beads being connected to electrically-conductive lines on said electronic component and to electrically-conductive lines on at least one heat sink, said beads carrying, on the one hand, electrical signals between the electronic component and each heat sink bearing said electrically-conductive lines and, on the other hand, the heat from the electronic component to each heat sink, via heat conduction.

The present invention concerns a process for manufacturing electronic circuits. It applies, in particular, to the manufacture of optoelectronic circuits and, more particularly, to improving the thermal behavior of a semiconductor emitting laser.

First Aspect.

Generally an emitting optical subassembly integrates the control electronics required to provide the polarization voltages and currents for the laser component and the laser itself. Such an assembly may take several different forms: a silicon base or other semiconductor that integrates the interconnecting lines between the various components, a silicon base or other structured semiconductors where the interconnections are provided by means of wires. In normal use, the laser operating in such a subassembly experiences temperature increases and variations according to external temperature conditions and also according to the conditions and the level of electrical injection.

Operating at a high temperature leads to the following inconveniences:

a much shorter life for the laser

a variation in the emitted wavelength detrimental to the operation of the systems in which the lasers are incorporated and

a saturation then a reduction in the power emitted that cannot be compensated for by increasing the injection current.

For this reason the vast majority of laser components, especially “Fabry-Perot” type of pulse emission lasers or distributed feedback (DFB) type of lasers, integrate a Peltier-type temperature regulator that makes it possible both to compensate for temperature fluctuations and to maintain an operating temperature close to the ambient temperature (25° C.). This solution introduces a significant cost and additional complexity into the assembly of laser components. Moreover these temperature regulators are relatively large in size and handicap the integration and miniaturization of emitters that the telecommunications industry is currently engaged in.

Vertical Cavity Surface Emitting Lasers (VCSELs) also experience the same types of problems described above and these are often magnified, especially in the case of vertical cavity emitting lasers using quaternary material on an InP substrate for long emitting wavelengths (1.25 μm to 1.65 μm). Indeed, the mirrors known as Bragg mirrors constituted of the periodic stacking of GaInAsP and InP materials are poor heat conductors and do not allow a high-temperature operation for this type of laser.

The aim of this invention is to eliminate or at the very least significantly reduce the heat problems for side and vertical emitting lasers. To this end, this invention proposes different types of micro-assembly depending on the nature of the laser (side or vertical emitting) using flip mounting of the laser component on a semiconductor that is a good heat conductor, microbeads being used both as electrical conductors for the laser's control signals and as heat conductors for cooling the laser.

Thus, according to its first aspect, this inventions envisages an assembly comprising an electronic component, characterized in that said component is connected by microbeads to at least one heat sink, said beads being connected to electrically-conductive lines on said electronic component and to electrically-conductive lines on at least one heat sink, said beads carrying, on the one hand, electrical signals between the electronic component and each heat sink bearing said electrically-conductive lines and, on the other hand, the heat from the electronic component to each heat sink, via heat conduction.

According to particular features, the assembly as described in brief above comprises a coating that coats the beads, at least one part of the electronic component and at least one part of a heat sink, said coating being an element that is a heat conductor and also an electrical insulator.

According to particular features, at least one heat sink is integrated into a housing of the electronic component.

According to particular features, at least one heat sink also makes up a part of a housing of the electronic component.

According to particular features, at least one heat sink integrates a generator of current and modulation and/or electronics allowing the electronic component to operate and/or be monitored.

According to particular features, one heat sink is created using a semiconductive material and in which a second heat sink is a mounted semiconductor or metallic element.

According to particular features, at least one heat sink comprises a hole facing said electronic component and in which said component is an optoelectronic component.

According to particular features, the assembly as described in brief above comprises an optical fiber in said hole.

Correlatively, according to its first aspect, this invention envisages a process for assembling an electronic component, characterized in that it comprises:

a step of preparing at least one heat sink for which, over at least one said heat sink, electrically-conductive lines are linked to mounts for beads and

a step of connecting, by microbeads, said electronic component to at least one heat sink, said beads being linked to electrically-conductive lines on said electronic component and to mounts for beads on the heat sink, said beads carrying, on the one hand, electrical signals between the electronic component and each heat sink bearing said electrically-conductive lines and, on the other hand, the heat from the electronic component to each heat sink, via heat conduction.

According to particular features, the assembly process as described in brief above comprises a step of closing a housing comprising at least one said heat sink.

In this way, the process that is the subject of the first aspect of this invention utilizing bead assemblies thus makes possible better heat management of the components and also the realization at the same time of interconnections for the laser diode's modulation current and direct current inputs. Using bead connections enables secondary radiations to be minimized because of the beads' small size compared to using wires and thus also to ensure better integrity for the microwave signals. In addition, the rear surface of the component being thus accessible, this invention allows substrate to be removed and the deposition or mounting of a metallic element with high heat dissipation qualities enabling the laser device's behavior at high temperature to be improved. The invention applies in a similar way to side and vertical emitting laser components.

Second and Third Aspects.

This invention also envisages a process and a device for coupling optical components. It applies, in particular, to the coupling of an optical fiber on a component emitting or receiving light signals.

The need to produce optoelectronic modules for high-speed optical fiber networks (10 GBd and above) at low cost and seeking geometric dimensions that are minimized has led to the development of optical subassemblies based on the use of optoelectronic chips of the VCSEL (the acronym for Vertical Cavity Surface Emitting Lasers) laser type in the case of emitters, or photodiode type (reverse bias PIN type or Avalanche type) in the case of receivers.

Various methods have been utilized to realize the optical coupling of the laser to the optical fiber or of the optical fiber to the photodiode. The most conventional ones use, on the optical fiber input, a component placed in a TO (acronym for Transistor Outline) housing equipped with an optical lens allowing the beam to be focused towards an optical fiber, which is secured to the TO housing, at the end of what is known as an “active” alignment phase, during which the rate of optical power coupled in the fiber is measured continuously.

An example of a description of these methods is the document by Trewhella et al., Evolution of optical subassemblies in IBM data communication transceivers, IBM J. Res. & Dev., 47, 2003.

This method is costly, both with regard to the cost of the mechanical parts comprising the assembly and with regard to the time for implementing the assembly process. Furthermore they suffer from two major inconveniences:

they do not integrate the laser's control electronics in the housing, in particular its pilot circuit (driver)—this is particularly important in the context of very high frequency applications—and

they do not allow the coupling of several laser chips, for what are known as parallel optics applications, to be carried out.

Another method was proposed in 1991 by Tai et al. in the publication “Self aligned fibre pigtailed surface emitting lasers on Si submount, Elec. Letters, 27, 1991” In this method, the emitting component is constituted by mounting the VCSEL emitting chip on a silicon substrate. A hole is formed through the substrate such that a fiber already cleaved and then inserted in the hole is guided by the latter and finds itself positioned in a passive way (i.e. without any need to make the laser emit during this operation) facing the VCSEL laser's emission area.

A similar approach was followed in the publication by Hayashi and Tsunetsugu, “Optical Module with MU Connector Interface Using Self-alignment Technique by solder bump Chip Bonding, ECTC, 1996”. The repeatability and accuracy of the chip's positioning on the substrate are therefore guaranteed by the mounting of the chip via what is known as a “flip-chip” (or IBM C4) technology on the substrate. This technology makes it possible in particular to obtain bit-rates in the order of 10 GBd more easily than by using more traditional technologies, such as cable twisting. Moreover the self-aligning properties of the fusible beads used by the flip-chip technology make it possible to guarantee the repeatability of the chip's positioning with respect to the hole guiding the optical fiber, this latter itself being positioned with respect to the chip and fixed on the substrate by passive alignment. In this publication, it should nevertheless be noted that the fiber is not guided directly into the substrate but is glued in a ceramic capillary tube (known as a “rod”) itself guided in a hole formed through the substrate.

Using “flip-chip” technology allows lateral and transversal positioning (i.e. in the two axes of the substrate's plane) of the optical fiber with respect to the chip (see, for example, patent application US2003/0098511, Moon et al.), however the fiber retains a degree of freedom in the optical axis, which makes its axial position with respect to the chip, and therefore the optical power coupled in the fiber, difficult to control. These two dimensions are in fact directly connected. Patents U.S. Pat. No. 4,779,946 (Pimpinella et al.) and U.S. Pat. No. 5,247,597 (Blacha et al.) propose producing the through hole by etching the silicon, thus making it possible to obtain a hole with a linearly variable cross-section such that the fiber introduced in this hole finds itself mechanically blocked longitudinally with respect to the optical axis when the optical fiber's diameter is equal to the hole's cross-section. The distance remaining between the chip and the fiber is thus fixed in a unique way by the characteristics of the etching of the silicon.

These latter technologies thus present the inconvenience of being unable to give an optical coupling rate that can be adjusted according to the application envisaged and obtained in a repeatable way once the value of the coupling rate wished for has been selected.

Furthermore, documents do not resolve any of the problems that are experienced in parallel optics and do not envisage any integration of the control electronics on the substrate.

The aim of this invention is to remedy these inconveniences.

To this end, this invention envisages, according to its second and third aspects, a device and a process of coupling optical components making it possible to ensure the position of the fiber's optical surface is controlled with respect to the emitting or detecting surface of the optoelectronic chip used as emitter or receiver, and a device resulting from the utilization of this process.

According to a second aspect, this invention envisages an optoelectronic device presenting a pre-defined coupling rate, characterized in that it comprises:

a substrate on which is mounted at least one optoelectronic component,

at least one calibrated hole passing through the substrate, each calibrated hole facing an optoelectronic component and being intended to guide an optical fiber in the direction of said optoelectronic component and

at least one optical fiber fixed in a fiber carrier, and projecting from said fiber-carrier by a pre-defined length, the projecting portion being inserted in a said hole, facing an optoelectronic component, in such a way that, when said fiber carrier is touching the substrate surface opposite the mounting pad of the optoelectronic component, the gap between the active surface of the optoelectronic component and the end of the optical fiber corresponds to the pre-defined coupling rate.

Thanks to these provisions, the positioning of the optical fiber can be carried out in a passive way, i.e. without powering up a laser or measuring the quantity of light passing through the optical fiber or received by the photodiode, which makes manufacturing the coupling device simpler and more economical.

Furthermore, utilizing a fiber carrier enables excellent repeatability of the respective positioning of the fiber with respect to the optoelectronic component.

It is noted that the pre-defined coupling rate may be voluntarily limited in order not to exceed coupled power levels in the fiber incompatible with the levels of ocular safety required by the standards in force.

According to particular features, at least one optoelectronic component is a laser.

According to particular features, at least one laser is a VCSEL-type laser, i.e. a Vertical Cavity Surface Emitting Laser.

According to particular features, the device as described in brief above comprises, on said substrate, for at least one optoelectronic component, its control circuit, or driver, and electrical tracks linked on the one hand to the control circuit and, on the other hand, to the optoelectronic component and allowing microwave signals to be propagated between said driver's control circuit and said laser.

According to particular features, at least one optoelectronic component is a photodiode.

According to particular features, at least one photodiode is PIN-type or Avalanche-type.

According to particular features, the optoelectronic device as described in brief above comprises, on the same substrate:

a plurality of optoelectronic components,

a plurality of calibrated holes passing through the substrate, each calibrated hole facing an optoelectronic component and being intended to guide an optical fiber in the direction of said optoelectronic component and

a plurality of optical fibers fixed in a fiber carrier, each fiber projecting from said fiber carrier by a pre-defined length, this projecting portion being inserted in a said hole, facing the associated optoelectronic component, in such a way that, when said fiber carrier is touching the substrate surface opposite the mounting pad of the optoelectronic components, the gap between the active surface of each optoelectronic component and the end of the associated optical fiber corresponds to the pre-defined coupling rate.

It is noted that the pre-defined length of the projecting portions is not necessarily identical for all the fibers.

According to particular features, said holes are arranged on lines, each of which comprises at least three holes.

According to particular features, at least one hole has a shape in which the diameter of the circle inscribed is greater than the diameter of an optical fiber and in which the circle inscribed has, with said shape, three points of contact forming a noticeably equilateral triangle.

Thanks to these provisions, the fiber may be precisely positioned in the hole while leaving room so that, by capillary action, adhesive might fill the space between the edges of the hole and the fiber. Indeed, the distance between the fiber and the edges of the hole is variable over the circumference of the fiber.

According to particular features, at least one fiber carrier has the shape of a rod.

According to particular features, said fiber carrier is constituted of several parts fixed to each other, the part in contact with the fiber being a capillary tube equipped with a hole whose diameter is close to the external diameter of the fiber.

The parts in question may be fixed in different ways, for example by press-fitting, gluing or soldering.

According to particular features, at least one fiber carrier is constituted of at least one part bearing at least one groove in which an optical fiber may be at least partially inserted so as to block the optical fiber by tightening said part against another part. Traditionally this fiber carrier is called a “V-groove”.

According to particular features, the end of at least one optical fiber is cleaved.

According to particular features, the end of at least one optical fiber is lenticular or with an extended core. Thanks to these provisions, the optical coupling is optimized and repeatable.

According to particular features, the cleaving presents an angle with respect to the plane perpendicular to the fiber.

According to particular features, the end of at least one fiber is cleaved and covered with an antireflection treatment.

Thanks to these provisions, secondary reflections at the fiber/air interface are limited. For example, said angle has a value of between 4 and 8° to stop the reflected luminous flux being re-coupled in the laser cavity, or towards the fibered network.

According to particular features, the gap between the active surface of the optoelectronic component and the end of the optical fiber is filled with a transparent material whose optical index is close to that of the optical fiber.

Thanks to these provisions, the light reflection on the optical fiber and/or the optoelectronic component is reduced.

According to a third aspect, this invention envisages a process for manufacturing a device as described in brief above presenting a pre-defined coupling rate, characterized in that it comprises:

a step of mounting, on a substrate, at least one optoelectronic component,

a step of producing at least one calibrated hole passing through said substrate, each calibrated hole facing an optoelectronic component and being intended to guide an optical fiber in the direction of said optoelectronic component and

a step of inserting, in at least one hole, a projecting portion of a pre-defined length (L) of an optical fiber fixed in a fiber carrier and fixing said optical fiber to said substrate facing an optoelectronic component, where said fiber carrier is touching the substrate surface opposite the mounting pad of the optoelectronic component, the gap between the active surface of the optoelectronic component and the end of the optical fiber corresponding to the pre-defined coupling rate.

Thanks to these provisions, the positioning of the optical fiber can be carried out in a passive way, i.e. without powering up a laser or measuring the quantity of light passing through the optical fiber or received by the photodiode, which makes manufacturing the coupling device simpler and more economical.

According to particular features, during the step of mounting at least one optoelectronic component, at least one optoelectronic component is a laser.

According to particular features, during the step of mounting at least one optoelectronic component, at least one laser is a VCSEL-type laser, i.e. a Vertical Cavity Surface Emitting Laser.

According to particular features, during the step of mounting at least one optoelectronic component, there is also mounted, on said substrate, for at least one optoelectronic component, a control circuit for the driver, and electrical tracks linked on the one hand to the driver control circuit and, on the other hand, to the optoelectronic component and allowing a microwave signal to be propagated between said driver's control circuit and said laser.

According to particular features, during the step of mounting at least one optoelectronic component, at least one optoelectronic component is a photodiode.

According to particular features, during the step of mounting at least one optoelectronic component, at least one photodiode is PIN-type or Avalanche-type.

According to particular features, in the process as briefly described above:

during the step of mounting, on a substrate, at least one optoelectronic component, a plurality of optoelectronic components are mounted on the substrate,

during the step of producing at least one calibrated hole passing through said substrate, a plurality of calibrated holes are produced, each calibrated hole facing an optoelectronic component and being intended to guide an optical fiber in the direction of said optoelectronic component and

during the insertion step, a fiber fixed in a fiber carrier is inserted, in each of said holes, and said fiber is fixed to said substrate facing an optoelectronic component, where said fiber carrier is touching the substrate surface opposite the mounting pad of the optoelectronic component, the gap between the active surface of the optoelectronic component and the end of the optical fiber thus corresponding to the pre-defined coupling rate.

According to particular features, during said insertion step, said holes are arranged on lines, each of which comprises at least three holes.

According to particular features, during the step of producing at least one calibrated hole, at least one hole has a shape in which the diameter of the circle inscribed is greater than the diameter of an optical fiber and in which the circle inscribed has, with said shape, three points of contact forming a noticeably equilateral triangle.

According to particular features, during the insertion step, at least one fiber carrier has the shape of a rod.

According to particular features, during the insertion step, the end of at least one optical fiber is cleaved.

According to particular features, the cleaving of said fiber presents an angle with respect to the perpendicular plane at the fiber.

According to particular features, the process as briefly described above comprises a step of filling the gap between the active surface of the optoelectronic component and the end of the optical fiber with a transparent material whose optical index is close to that of the optical fiber.

According to particular features, during the mounting step, a “flip-chip” method is utilized.

According to particular features, the step of mounting via a “flip-chip” method comprises a step of mounting metallized contacts on said substrate, a step of depositing a fusible material on said metallized contacts and a step of re-fusing said fusible material during which the fusible material takes the form of a bead of a controlled diameter.

According to particular features, the step of mounting via a “flip-chip” method comprises a step of mounting, on the optoelectronic component, metal contacts corresponding to the position of the substrate's beads.

Thanks to these provisions, the device possesses very good microwave signal transmission performance qualities and the assembly benefits from a self-alignment of each optoelectronic component making it possible to control the position of the optoelectronic component with respect to the guiding hole for the fibers.

Because of this, the passive alignment of the fiber and the optoelectronic component in the substrate plane enables high repeatability of the rate of optical coupling between the optoelectronic component and the corresponding optical fiber.

According to particular features, during the mounting step, a plurality of optoelectronic components are mounted on a single common substrate and said common substrate is cut to the dimensions of substrates, each bearing at least one individual optoelectronic component.

Thanks to these provisions, manufacturing costs are further reduced.

As the characteristics, advantages and aims of the process are similar to those of the device as described in brief above, they are not repeated here.

Fourth and Fifth Aspects.

This invention also envisages an optoelectronic device and a process of manufacturing said device. It applies, in particular, to monitoring and regulating the emission power for a Vertical Cavity Surface Emitting Laser, known as VCSEL.

The development of VCSEL (Vertical Cavity Surface Emitting Lasers) optoelectronic components has opened up a vast field of application, ranging from gas detection to the production of optoelectronic components for optical fiber networks in short-distance networks. VCSEL lasers also present a certain number of advantages compared to pulse emission lasers, in particular their collective testability on pulse, greater ease of coupling in standard optical fibers, etc.

These components are used after being placed in a housing, traditionally in housings known as TO (Transistor Outline) or TOSA (Transmitter Optical Sub Assembly), respectively fitted with an aperture letting the light beam pass or a device allowing an optical fiber connector to be connected.

Most applications utilizing these components require being able to continuously measure the power emitted by the VCSEL by means of a sensor placed inside the housing, typically a PIN-type diode known as a “monitor photodiode”. The problem is thus of being able to illuminate this photodiode with a fraction of the light emitted by the VCSEL laser before it leaves the housing.

Traditionally, this problem is solved by making use of the secondary reflections that the beam encounters at the housing's outbound aperture: this fraction of the beam, reflected, can be detected by a photodiode:

placed in proximity to the VCSEL laser, as proposed by the document U.S. Pat. No. 5,905,750 (Lebby et al.),

on which the VCSEL laser is placed, as proposed by the document GB 2.351.180 (Oskarsson et al.), or

positioned behind the VCSEL laser, as proposed by the document U.S. Pat. No. 5,737,348 (Smith et al.).

The aperture on which a part of the light emitted by the VCSEL laser is reflected can also be inclined with respect to the axis of emission of the laser beam in order to redirect a part of it towards the monitor photodiode, placed next to the VCSEL, as proposed by the document WO 99/34487 (Smith et al.).

Other methods have also been proposed:

the monolithic integration of the detector and the VCSEL laser's chip, as proposed by the document U.S. Pat. No. 5,943,357 (Lebby et al.),

the detection lateral to the VCSEL laser of its spontaneous emission by a detector realized in proximity, as proposed by the document U.S. Pat. No. 5,757,836 (Jiang et al.),

directly integrating a detector on the optical path of the emitted light, so as to convert a part of the power into current, while letting a large part pass, as described in the documents EP 0.869.590 (Kiely et al.), WO 03/000019 (Cable et al.) and US 2003/0109142 (Cable et al.).

This invention envisages a device allowing the power of the VCSEL laser to be monitored by detecting the candlepower emitted from the side of the substrate on which the VCSEL laser has been realized, generally epitaxially.

Thus, according to a fourth aspect, this invention envisages an optoelectronic device, characterized in that it comprises:
a vertical emitting laser where the emission is accomplished on the one hand on what is known as an “effective” surface facing an optical system utilizing the rays emitted by said effective surface of said laser and, on the other hand, on a surface opposite to said effective surface and
an optoelectronic sensor adapted to pick up all or part of the light emitted by the laser through the surface opposite the effective surface.

Thanks to these provisions, it is the light emitted by the laser on the surface opposite the effective surface that is used to detect a laser malfunction or to monitor and regulate the candlepower emitted by the laser, obviating the need for an optical device for the effective surface of the laser. In addition, realizing and embedding a sensor on this surface opposite the effective surface is easy since there is no other optical component there.

Other advantages of this invention are a greater monitored power, increasing the signal/noise ratio and a heightened repeatability for the level of power with respect to the state of the art.

The sensor can thus be used to detect a possible malfunction of the VCSEL or to regulate its average power.

According to particular features, a host substrate bearing the laser by the surface opposite the effective surface is pierced by a hole between the laser and the optoelectronic sensor.

Thanks to these provisions, even if the material of the host substrate absorbs the light rays emitted by the laser, the optoelectronic sensor can pick up a part of the light emitted by the laser, through the host substrate piercing.

According to particular features, the optoelectronic device as described in brief above comprises, on said host substrate, for at least one laser, a control circuit for the driver and electrical tracks linked on the one hand to the driver control circuit and, on the other hand, to the laser and allowing a microwave signal to be propagated between said driver's control circuit and said laser.

Thanks to these provisions, the laser can emit microwave optical signals.

According to particular features, the optoelectronic sensor and the laser are each connected, by fusible beads, to a main substrate bearing at least one optical fiber.

Thanks to these provisions, the assembly technique known as “flip-chip” or “IBM C4” can be utilized, which ensures very high accuracy and very high repeatability for the manufacture of the optical sub-assembly, thus avoiding having to switch on the laser to carry out the positioning or calibration of the sensor.

According to particular features, the optoelectronic sensor comprises a photodiode. According to particular features, said photodiode is PIN-type and/or Avalanche-type.

According to particular features, the optoelectronic sensor bears an antireflection treatment facing said laser. In this way loss of light by reflection or diffusion is avoided.

According to particular features, the optoelectronic device as described in brief above comprises an optical fiber facing the effective surface of the laser.

Thanks to these provisions, the device can be used for transmitting optical signals over a distance, for example for carrying telecommunications signals.

According to particular features, the optoelectronic device as described in brief above comprises:

a plurality of vertical emitting lasers where the emission is accomplished on the one hand on what is known as an “effective” surface facing an optical system utilizing the rays emitted by said effective surface of said laser and, on the other hand, on a surface opposite to said effective surface, said plurality of lasers being mounted on at least one host substrate and

for each laser, an optoelectronic sensor adapted to pick up all or part of the light emitted by the laser via the surface opposite the effective surface.

This invention is thus especially suited to the case where several VCSEL lasers placed in one single housing must be monitored simultaneously: each VCSEL laser is thus equipped with a monitor photodiode individually measuring its power through its host substrate. Indeed, in this case, using reflection on part of the housing would not allow the respective powers of the VCSEL lasers to be distinguished.

According to a fifth aspect, this invention envisages a process for manufacturing optoelectronic devices, characterized in that it comprises:

a step of mounting, on a host substrate, a vertical emitting laser where the emission is accomplished on the one hand on what is known as an “effective” surface facing an optical system utilizing the rays emitted by said effective surface of said laser and, on the other hand, on a surface opposite to said effective surface and

a step of positioning an optoelectronic sensor adapted to pick up all or part of the light emitted by the laser through the surface opposite the effective surface.

According to particular features, the process as described in brief above comprises a step of piercing the host substrate bearing the laser by its surface opposite its effective surface, preceding the step of positioning the optoelectronic sensor.

As the characteristics, advantages and aims of the process are similar to those of the device as described in brief above, they are not repeated here.

Sixth and Seventh Aspects.

This invention also envisages a device allowing the power of the VCSEL laser to be monitored by detecting, directly, without reflection, the candlepower emitted from the side of the effective surface of the VCSEL laser, on a main substrate which bears an optical fiber.

Thus, according to a sixth aspect, this invention envisages an optoelectronic device, characterized in that it comprises a main substrate bearing:

an optical fiber,

a host substrate bearing a vertical emitting laser where the emission is accomplished on what is known as an “effective” surface facing said optical fiber and

an optoelectronic sensor placed facing the effective surface of the laser, in proximity to the inbound surface of the optical fiber and adapted to pick up a part of the light emitted by the laser in the direction of the main substrate.

Thanks to these provisions, it is the light emitted by the laser on the optical fiber side, without reflection on a surface, that is used to detect a laser malfunction or to monitor and regulate the candlepower emitted by the laser, obviating having a complicated optical device and experiencing fouling effects with a reflection surface. In addition, realizing and embedding a sensor on the main substrate are easy.

The optoelectronic device can be used for transmitting optical signals over a distance, for example for carrying telecommunications signals.

Other advantages of this invention are a greater monitored power, increasing the signal/noise ratio and a heightened repeatability for the level of power with respect to the state of the art.

The sensor can thus be used to detect a possible malfunction of the VCSEL or to regulate its average power.

According to particular features, the optoelectronic device as described in brief above comprises, on said host substrate, for at least one laser, a control circuit for the driver and electrical tracks linked on the one hand to the driver control circuit and, on the other hand, to the laser and allowing a microwave signal to be propagated between said driver's control circuit and said laser.

Thanks to these provisions, the laser can emit microwave optical signals.

According to particular features, the laser's host substrate is connected, by fusible beads, to the main substrate.

Thanks to these provisions, the assembly technique known as “flip-chip” or “IBM C4” can be utilized, which ensures very high accuracy and very high repeatability for the manufacture of the device, thus avoiding having to switch on the laser to carry out the positioning or calibration of the sensor.

According to particular features, the optoelectronic sensor comprises a photodiode. According to particular features, said photodiode is a metal-semiconductor-metal type.

Thanks to these provisions, the manufacturing costs of said sensor are very low.

Thanks to particular features, the laser's host substrate bears a mirror on the surface of this substrate opposite the effective surface of said laser.

Thanks to these provisions, the power of the laser is increased.

According to particular features, the optoelectronic sensor bears an antireflection treatment facing said laser. In this way loss of light by reflection or diffusion is avoided.

According to particular features, the optoelectronic device as described in brief above comprises a main substrate bearing:

a plurality of optical fibers,

at least one host substrate bearing a plurality of vertical emitting lasers where the emission is accomplished on what is known as an “effective” surface facing one optical fiber of said plurality of optical fibers and

for each laser, an optoelectronic sensor placed in proximity to the inbound surface of the corresponding optical fiber and adapted to pick up a part of the light emitted by said laser in the direction of the main substrate.

This invention is thus especially suited to the case where several VCSEL lasers placed in one single housing must be monitored simultaneously: each VCSEL laser is thus equipped with a monitor photodiode individually measuring its power. Indeed, in this case, using reflection on part of the housing would not allow the respective powers of the VCSEL lasers to be distinguished.

According to a seventh aspect, this invention envisages a process for manufacturing optoelectronic devices, characterized in that it comprises:

a step of mounting, on a main substrate, a host substrate bearing a vertical emitting laser where the emission is accomplished on what is known as an “effective” surface and an optoelectronic sensor placed facing the laser's effective surface, in proximity to the inbound surface of the optical fiber and adapted to pick up a part of the light emitted by said laser in the direction of the main substrate and

a step of positioning an optical fiber in proximity to said optoelectronic sensor and facing said effective surface of said laser.

As the characteristics, advantages and aims of the process are similar to those of the device as described in brief above, they are not repeated here.

Eighth to Fifteenth Aspects.

This invention also envisages a process and device for encapsulating electronic components.

Encapsulation and or packaging technologies are becoming more and more critical, both in terms of performance, hermeticity, resistance to shocks and vibrations and resistance to thermal cycles and variations, and in terms of cost. Moreover, the presentation or final “packaging” of a component or sub-system tends most often to be specific and must satisfy at one and the same time both the component or sub-system's integrity constraints and the constraints of a user-friendly interface in its integration into any system whatsoever.

The need to fulfill the specifications of resistance to environmental types of attacks, such as humidity or extremely wide ranges of temperature cycles, leads to the need to have a hermetic packaging. The quid pro quo lies in the technological difficulty of producing hermetic optical or electrical feed-throughs allowing a neutral atmosphere inside the housing or a high vacuum to be maintained.

The electrical feed-throughs are most often glass-metal feed-throughs well known in the vacuum and ultra-high vacuum industry. These feed-throughs represent moreover a significant cost impacting on the end product beyond price objectives when the markets concerned represent a large volume. This is even more the case when it is necessary to add an optical feed-through involving an optical fiber. The technologies used in the case of an optical fiber are also glass—metal soldering types of technologies. The added difficulty lies in maintaining the effectiveness of the optical coupling after soldering and the embrittlement of the optical fiber after soldering due to constraints introduced by the parameters of the soldering process, especially the temperature. The final cost, for example for a laser in a hermetic housing, is often prohibitive because of the techniques employed and the low manufacturing returns.

A large amount of research has been devoted to realizing housings on silicon wafers aimed at directly integrating the housing with its circuit or its multi-circuit assembly. The term used for these concepts is “wafer level packaging”. These techniques even solve the cost problems associated with the traditional technologies by realizing housings in a collective way and at the wafer level. These techniques are especially suited to microelectronics and photonics, fields requiring ever more advances in miniaturization. Today the hermeticity is realized by means of metal brazings (Aluminum, for example) obtained at high temperature. The alignment of the wafer housing with the wafer circuits is generally obtained by simple mechanical alignment.

As a general rule, these techniques present the following fault: the brazing temperature is high and can damage the components to be packaged. In addition, the alignment of the packaging housing is not perfect and does not allow the inclusion of optical components such as a ball lens enabling the coupling of the laser with a fiber. Finally, it is difficult to realize the brazing and at the same time maintain the vacuum in the housing.

The invention aims to remedy these inconveniences.

In a general way, the object of certain aspects of this invention is to use the wafer level packaging techniques by solving the points mentioned previously, namely:

realizing hermeticity from both an electrical and an optical view point through techniques other than glass metal solders and

obtaining substantial savings in terms of cost.

The invention also envisages producing, in a collective way and via conventional microelectronics technologies, a series of wafer housings with characteristics that make it possible to realize the assembly in a collective way. The invention proposes a solution for realizing the housing's hermetic seal at low temperature. The invention also concerns the realization of hermetic electrical and/or optical feed-throughs allowing the active electrical and/or optical elements incorporated inside the hermetic housing to be interfaced with the outside environment.

According to an eighth aspect, this invention envisages avoiding the “ground plane” effect, which interferes with the signals transmitted, generated by the metal housing when this is too close to a microwave line.

To this end, the present invention envisages, according to its eighth aspect, a process of encapsulating at least one electronic component, which comprises:

a step of preparing a substrate comprising the realization of a first layer of dielectric material on a first surface of said substrate,

a step of realizing a conductive line on said first layer of dielectric material,

a step of piercing a hole from a second surface of the substrate opposite said first surface up to the conductive line and

a step of filling said hole with a conductive material.

Thanks to these provisions, the signals and the conductive lines, especially the lines carrying microwave signals, are away from the side of the metal housing that might cause interference with them due to the “ground plane” effect.

According to particular features, the process as briefly described above comprises a step of realizing a second layer of dielectric material over the first layer of dielectric material, and over the conductive line.

Thanks to these provisions, the risks of the hole damaging the conductive line are reduced.

According to a ninth aspect, to avoid positioning problems, the cross-section of the housing is reduced, with respect to the average thickness of the housing, on the edges of the housing abutting against the substrate. A “knife” is thus formed, which is sunk into the substrate, or into an intermediary solid layer of the substrate and serving as a seal between the substrate and the housing.

Thus, the present invention envisages, according to its ninth aspect, a process of encapsulating at least one electronic component, which comprises:

a step of preparing a housing presenting, on its edges intended to abut against the substrate bearing each said electronic component, a thickness at least two times less than the average thickness of said housing and

a step of positioning said housing on said substrate, said knife thus abutting against said substrate.

Correlatively, the ninth aspect of this invention envisages a packaging process, which comprises:

a step of preparing a substrate bearing each said electrical component so that it presents, facing the edges of a housing intended to abut against said substrate, a knife presenting a thickness at least two times less than the average thickness of said housing and

a step of positioning said housing on said substrate, said edges thus abutting against said knife.

According to particular features, said edges present a basically triangular cross-section.

Thanks to these provisions, the contact of the housing on the substrate is very concentrated and prohibits subsequent sliding movements by the housing on the substrate.

According to particular features, the process as briefly described above comprises a step of realizing a seal in a ductile material which said knife comes into contact with during the positioning step.

Thanks to these provisions, the knife can be sunk into said seal and ensure better hermeticity, in particular when a negative pressure is applied in the housing's interior volume.

According to particular features, said ductile material is comprised of Indium.

According to particular features, the packaging process as described in brief above comprises a step of placing the volume comprising said housing and said substrate in a vacuum, at least partial.

Thanks to these provisions, the housing is maintained in position on the substrate by the negative pressure created inside the housing. The vacuum considered is such that for preference the residual pressure is less than 10⁻⁴ Torr.

According to particular features, during the vacuum step, in a pump line, metal, initially arranged at the exit of said line, is melted.

Thanks to these provisions, the plugging of the pump line is easy and final.

According to particular features, the metal to be melted presents, initially, the form of a bead.

According to particular features, the metal to be melted comprises Indium.

Thanks to each of these provisions, a micro-gate is realized at the exit from the pump line and, with the bead being heated to a temperature of approximately 170° C., said line is plugged.

According to particular features, during the fusing of said metal, a slight overpressure is applied to the outside of the housing, with respect to the vacuum, at least partial, inside the housing.

Thanks to these provisions, the metal in fusion is drawn to the interior of the line to be plugged.

According to particular features, the process as described in brief above comprises the realization of the packaging of several components on one single substrate with several housings then the cutting of the substrate so as to separate the packaged components with their housings.

Thanks to these provisions, the cost of packaging electronic components is reduced.

According to a tenth aspect, the present invention envisages reducing the difficulty of realizing an optical link between an optoelectronic component, for example a laser or a photodiode, and an optical fiber extending outside a housing comprising said optoelectronic component.

Thus, the present invention envisages, according to its tenth aspect, a process of packaging an optoelectronic component utilizing light in a pre-defined spectral band, which comprises:

a step of preparing a housing so as to form in it an aperture of material at least partially transparent in said spectral band,

a step of positioning said housing facing said optoelectronic component in such a way that said aperture is facing said component and

a step of positioning an optical fiber on said housing in such a way that an outside surface of said optical fiber is facing said aperture.

According to particular features, said housing is comprised of a material at least partially transparent in said spectral band.

Correlatively, the tenth aspect of this invention envisages a packaging process for an optoelectronic component utilizing a spectral band of light, which comprises:

a step of preparing the substrate so as to form in it an aperture of material at least partially transparent in said spectral band,

a step of positioning said optoelectronic component on said substrate in such a way that said aperture is facing said component and

a step of positioning an optical fiber on said housing in such a way that an outside surface of said optical fiber is facing said aperture.

According to particular features, said aperture presents a thickness of less than 100 μm.

According to particular features, said material at least partially transparent in said spectral band is quartz. In effect, quartz is transparent for the wavelength 850 nm and silicon between 1310 nm and 1550 nm, these wavelengths being used currently in optoelectronics.

According to particular features, during the step of positioning the housing facing the optoelectronic component, said optoelectronic component is mounted on said housing by a technology utilizing beads of fusible material. This technology is known under the name “flip-chip”. The positioning of the optoelectronic component with respect to the aperture is thus very accurate, in each dimension.

An eleventh aspect of this invention envisages increasing the accuracy of positioning a housing with respect to an electronic component borne on a substrate.

To this end, according to an eleventh aspect, the present invention envisages a packaging process, characterized in that it comprises:

a step of forming, on the substrate and on at least one part of the sides of the housing, bead or cylinder mounts in a fusible material,

a step of depositing fusible material on at least one part of said bead or cylinder mounts,

a step of fusing said fusible material so as to form said beads or cylinder with precisely defined dimensions and

a step of positioning beads or cylinder mounts not yet bearing said beads or cylinder on said beads or cylinders.

Thanks to these provisions, the positioning of the housing on the substrate is very accurate and is controlled by the presence of the beads.

All the particular and general features of the various aspects of the present invention constitute particular features of the preceding aspects of the present invention and aim to constitute a packaging process presenting the advantages and particular characteristics of each one of the aspects of the present invention.

According to a twelfth aspect, this invention envisages a device for encapsulating at least one electronic component, characterized in that it comprises:

a substrate,

a first layer of dielectric material on a first surface of said substrate,

a conductive line on said first layer of dielectric material,

a hole extending from a second surface of the substrate opposite said first surface up to the conductive line.

According to a thirteenth aspect, this invention envisages a device for encapsulating at least one electronic component, which comprises:

a substrate bearing each said electrical component and

a housing presenting, on its edges intended to abut against said substrate, a knife with a thickness at least two times less than the average thickness of said housing.

Correlatively, according to its thirteenth aspect, this invention envisages a device for encapsulating at least one electronic component, which comprises:

a housing and

a substrate bearing each said electrical component which presents, facing the edges of a housing intended to abut against said substrate, a knife presenting a thickness at least two times less than the average thickness of said housing.

According to a fourteenth aspect, the present invention envisages a process of packaging an optoelectronic component utilizing a spectral band of light, which comprises:

a housing presenting an aperture of material at least partially transparent in said spectral and facing said component and

an optical fiber positioned on said housing in such a way that an outside surface of said optical fiber is facing said aperture.

According to a fifteenth aspect, this invention envisages a device for encapsulating an electronic component, which comprises:

on at least one part of the sides of the housing, bead or cylinder mounts in a fusible material,

a substrate bearing said component and, facing the edges of the housing, bead or cylinder mounts in a fusible material,

beads or a cylinder connecting said beads or cylinder mounts.

As the advantages, aims and characteristics of the various aspects of the device that is the subject of the present invention are similar to those of the process that was the subject of the present invention, they are not repeated here.

Other advantages, aims and characteristics of the present invention will become apparent from the description that will follow, made, as an example that is in no way limiting, with reference to the drawings included in an appendix, in which:

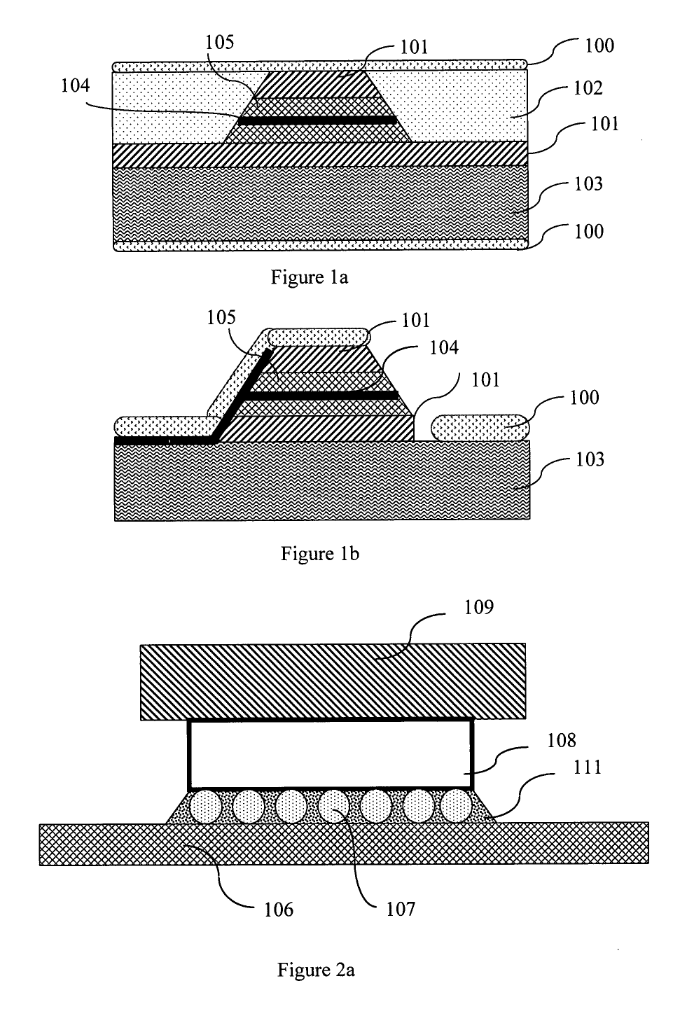

FIG. 1a represents, schematically, a cross-section of a conventional pulse emitting laser having one contact on the front surface and one contact on the rear surface;

FIG. 1b represents, schematically, a conventional pulse emitting laser having both contacts on the front surface;

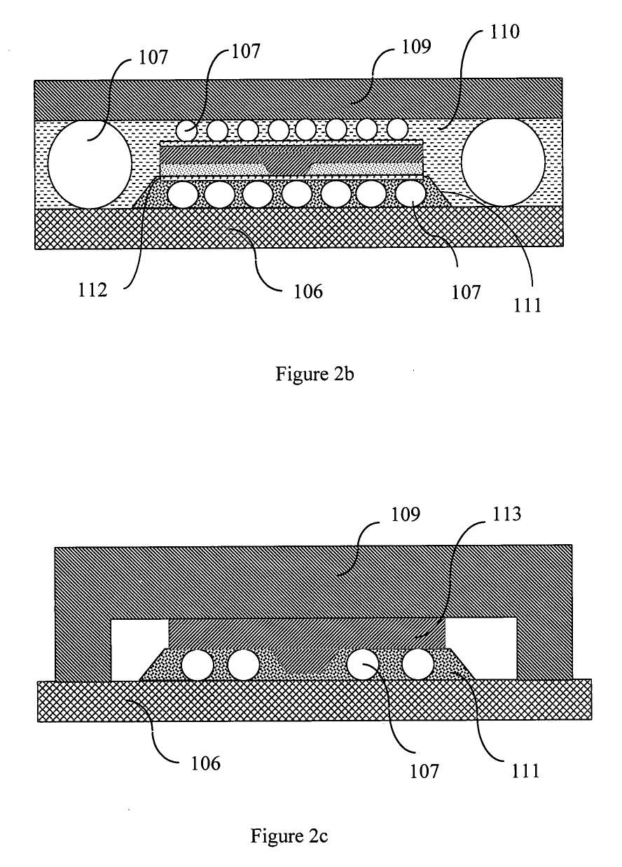

FIGS. 2a and 2b represent a schematic diagram of the invention and an example of a heat sink and laser assembly as proposed in the invention;

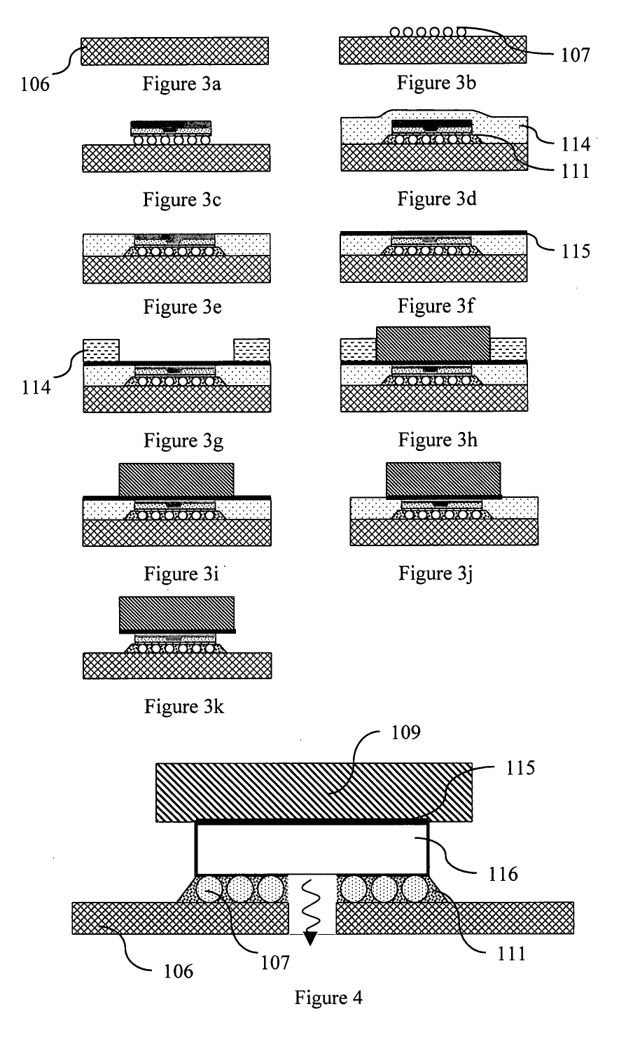

FIGS. 3a thru 3k represent, schematically, a manufacturing process for the invention in the case of a side emitting laser where the two contacts are located on the same surface;

FIG. 4 represents, schematically, an application of the invention in the special case of a vertical emitting laser;

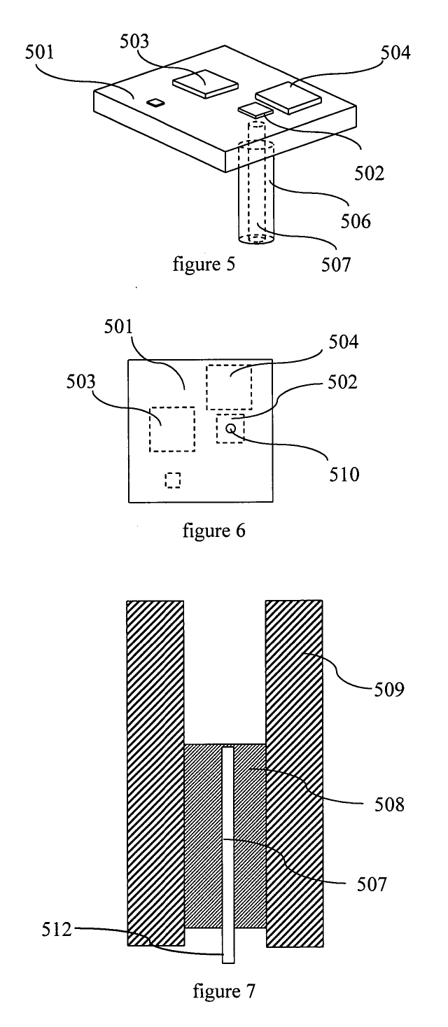

FIG. 5 represents, schematically, in perspective, a first particular embodiment of a device that is the subject of this invention, after assembly;

FIG. 6 represents, schematically and in a front view, the first embodiment shown in FIG. 5;

FIG. 7 represents, schematically, a part of the particular embodiment shown in FIG. 5, before assembly;

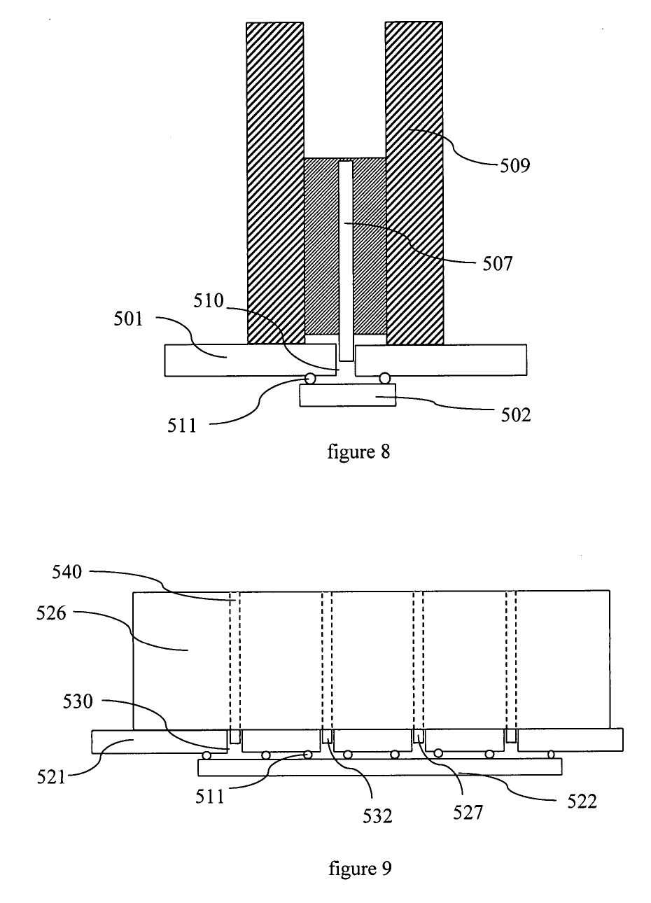

FIG. 8 represents, schematically, the part of the particular embodiment shown in FIG. 7 in the substrate shown in FIG. 6, after assembly;

FIG. 9 represents a particular embodiment of this invention in a parallel optics device;

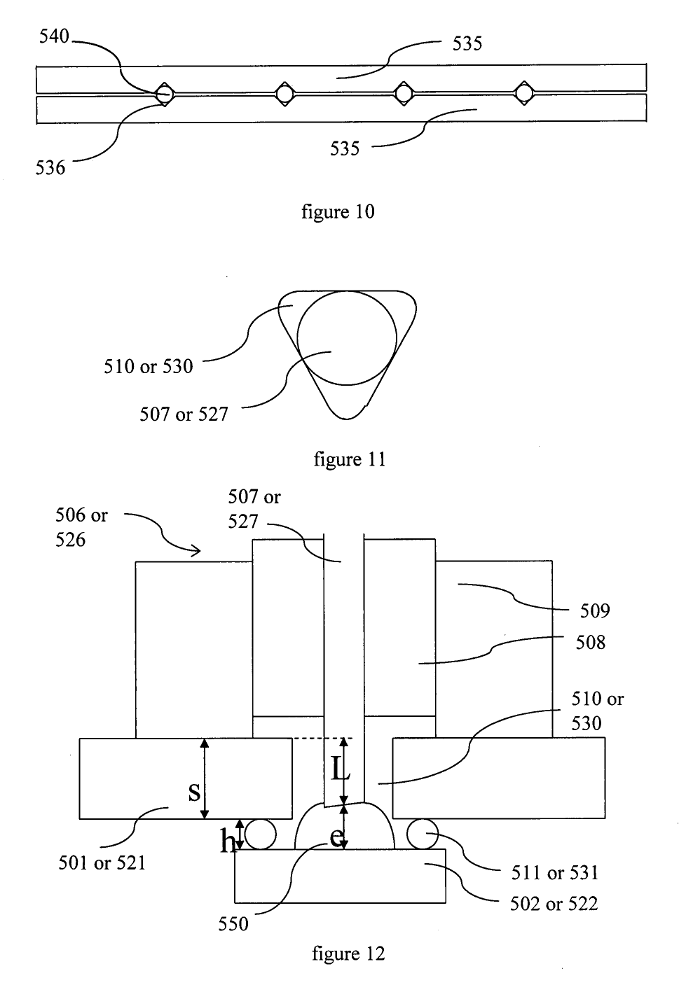

FIG. 10 represents, in cross-section, a band of optical fibers and a fiber carrier utilized in the embodiment shown in FIG. 9;

FIG. 11 represents, in cross-section, a hole utilized in the embodiments shown in FIGS. 5 thru 10;

FIG. 12 represents, in cross-section, a particular embodiment of the optical coupling between an optical fiber and an optoelectronic component, coupling able to be utilized in the particular embodiments shown in FIGS. 5 thru 11;

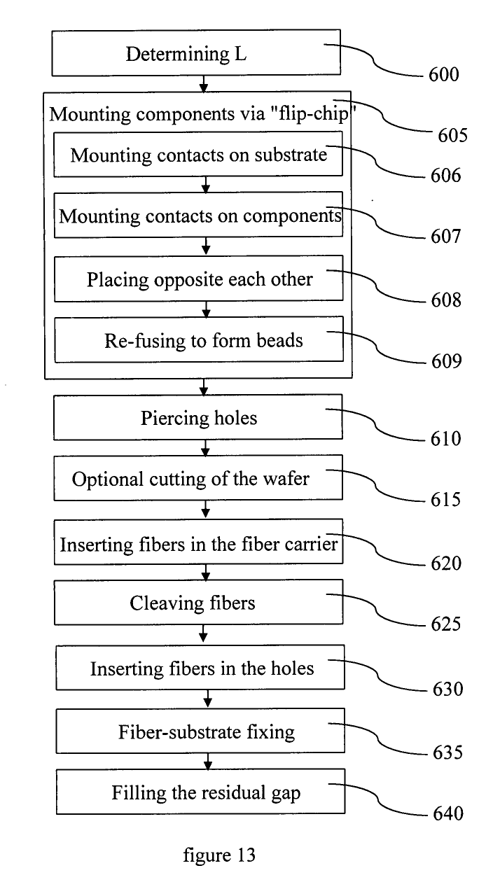

FIG. 13 represents, in the form of a logical diagram, steps utilized in a particular embodiment of the process that is the subject of the present invention;

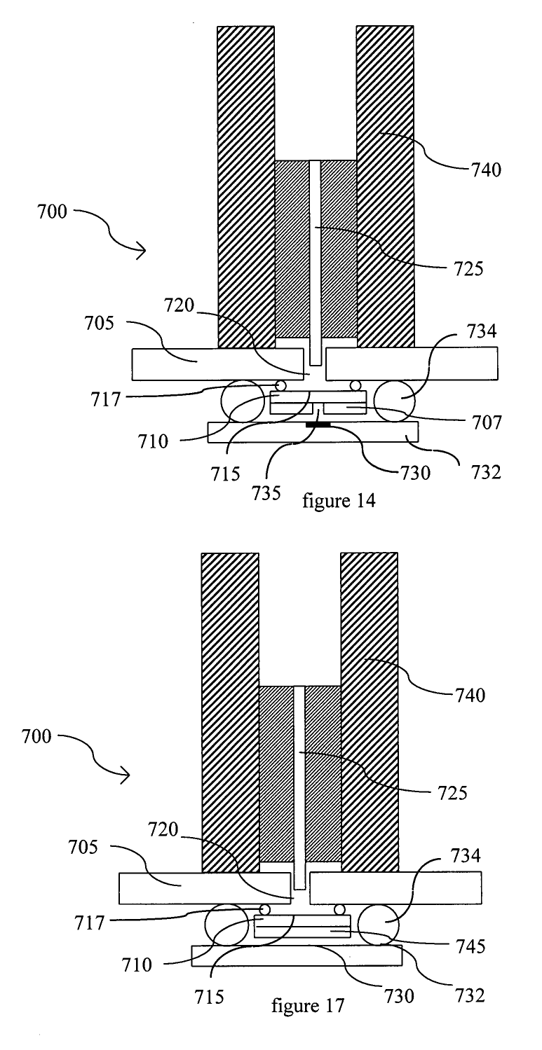

FIG. 14 represents, schematically, in section, a first particular embodiment of a device that is the subject of this invention, after assembly;

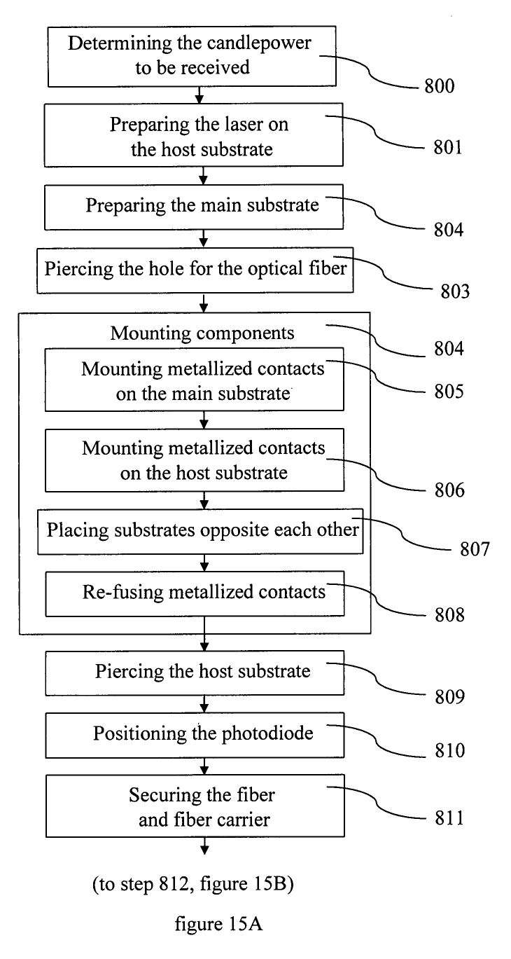

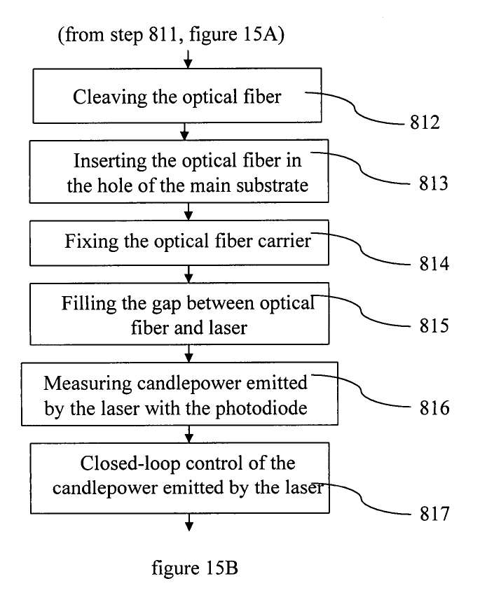

FIGS. 15A and 15B represent a logical diagram of steps utilized in a particular embodiment of a manufacturing process of the device shown in FIG. 14;

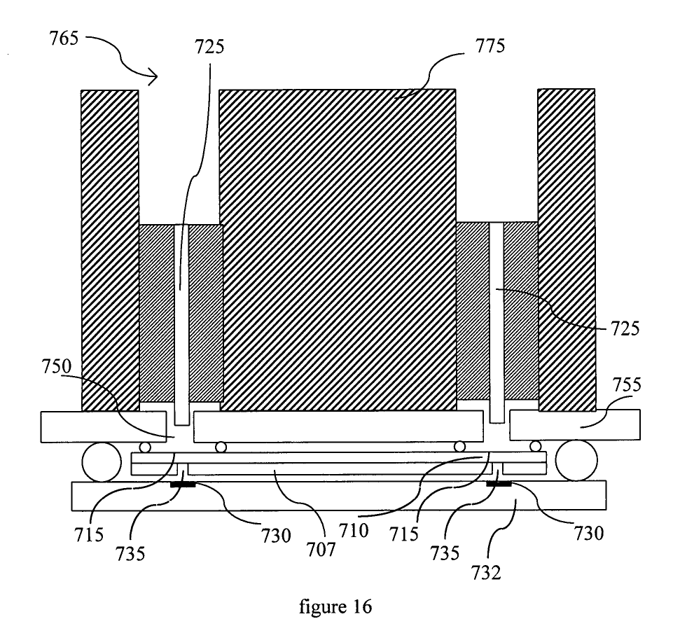

FIG. 16 represents, schematically, in section, a second particular embodiment of a device that is the subject of this invention, after assembly;

FIG. 17 represents, schematically, in section, a third particular embodiment of a device that is the subject of this invention, after assembly;

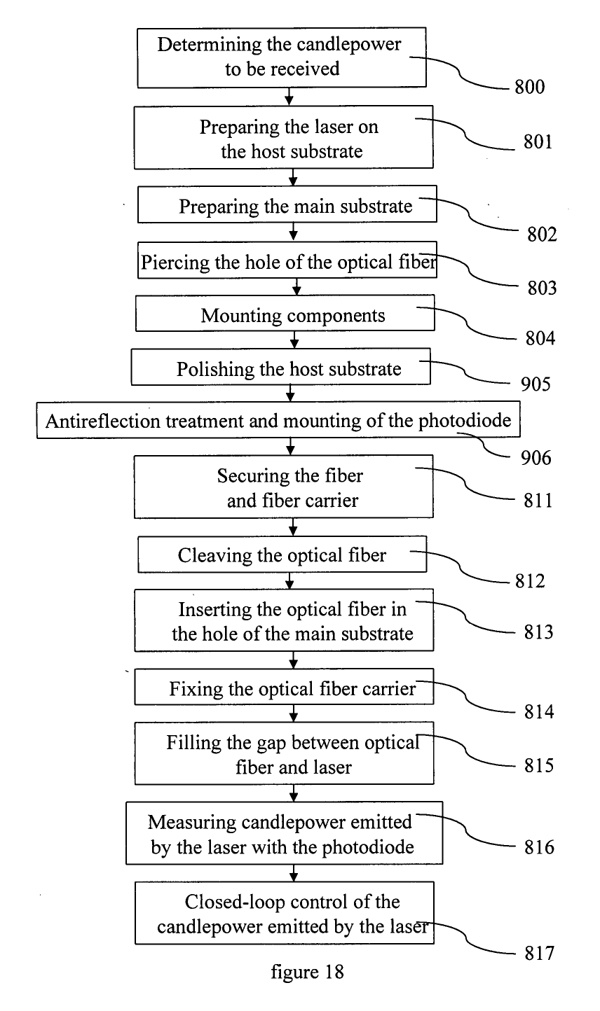

FIG. 18 represent a logical diagram of steps utilized in a particular embodiment of a manufacturing process of the device shown in FIG. 17;

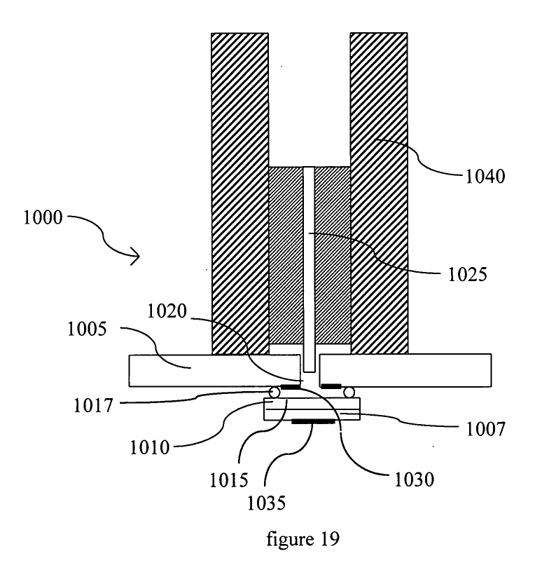

FIG. 19 represents, schematically, in cross-section, a first particular embodiment of a device that is the subject of this invention, after assembly;

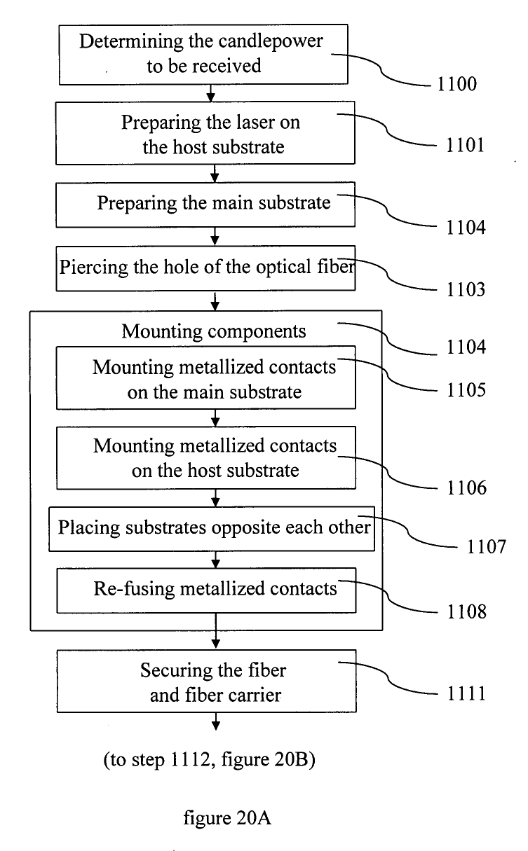

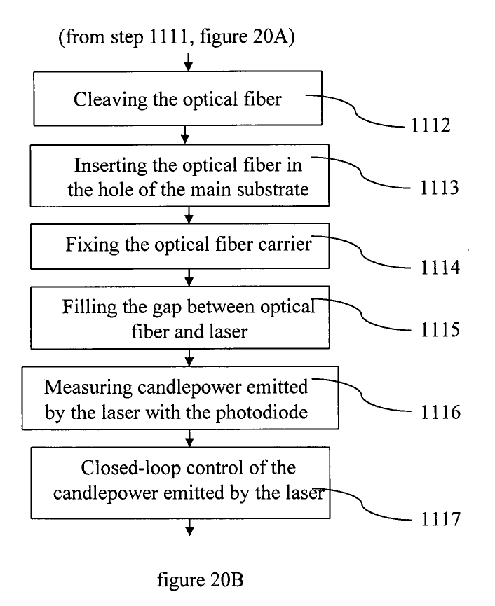

FIGS. 20A and 20B represent a logical diagram of steps utilized in a particular embodiment of a manufacturing process of the device shown in FIG. 19;

FIG. 21 represents, schematically, in cross-section, a second particular embodiment of a device that is the subject of this invention, after assembly;

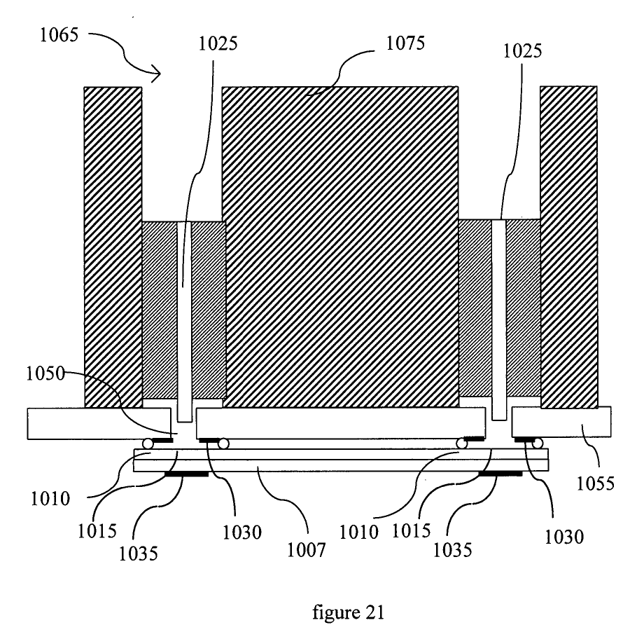

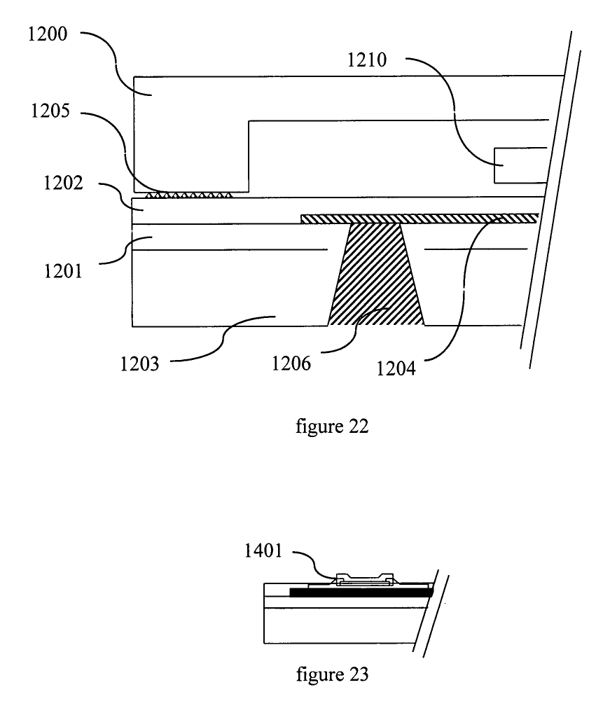

FIG. 22 represents, schematically, in cross-section view, a particular embodiment of a feed-through of a conductive line for inbound or outbound electrical signals;

FIGS. 23 thru 26 represent, schematically, a particular embodiment of a series of packaging steps in a second particular embodiment of an electronic component packaging;

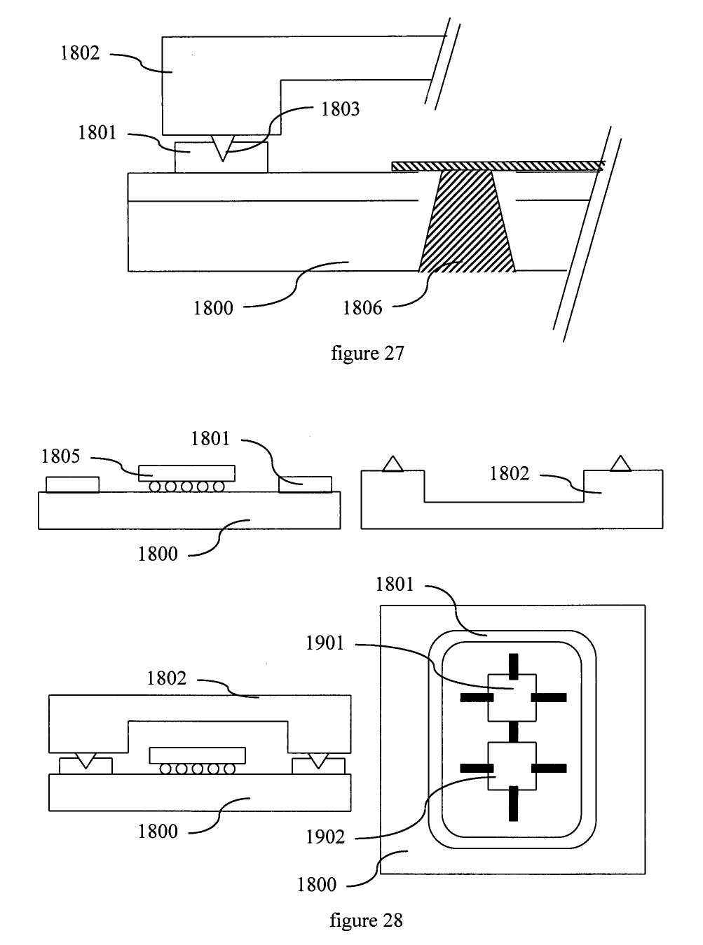

FIGS. 27 and 28 represent, schematically, a third particular embodiment of an electronic component packaging;

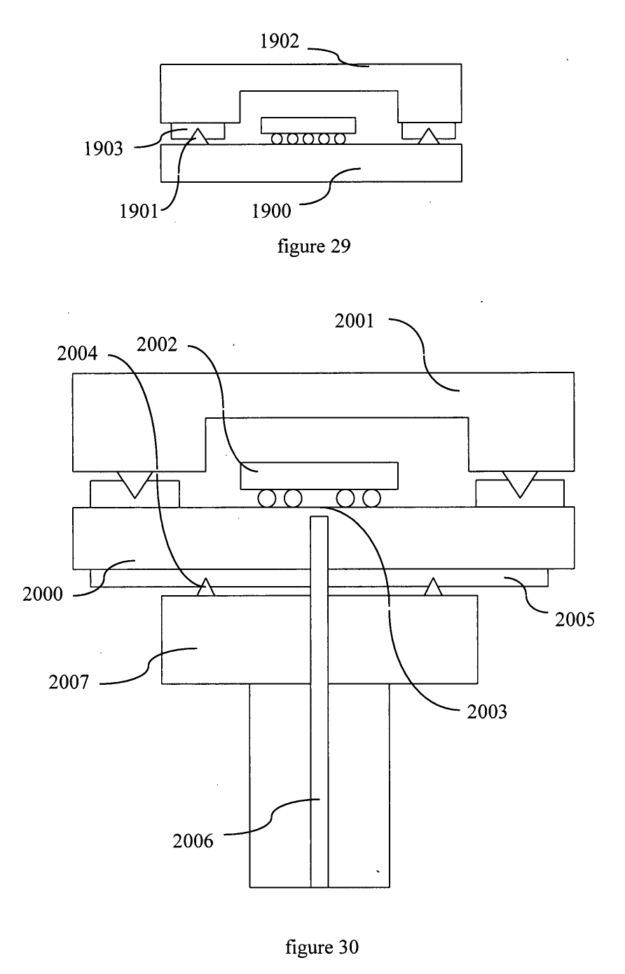

FIG. 29 represents, schematically, a fourth particular embodiment of an electronic component packaging;

FIG. 30 represents, schematically, a fourth particular embodiment of an electronic component packaging, adapted to the packaging of an optoelectronic component;

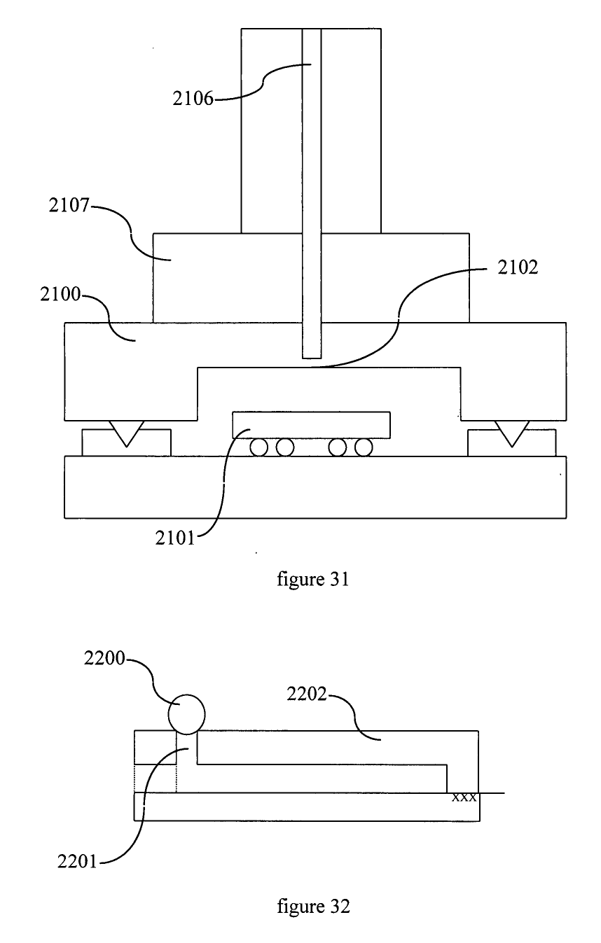

FIG. 31 represents, schematically, a fifth particular embodiment of an electronic component packaging, adapted to the packaging of an optoelectronic component and

FIG. 32 represents, schematically, an embodiment of making a housing hermetic via micro-gate.

It is noted that FIGS. 1 thru 4 refer to the first aspect of this invention, FIGS. 5 thru 13 refer to the second and third aspect of this invention, FIGS. 14 thru 18 to the fourth and fifth aspect of this invention, FIGS. 19 thru 21 to the sixth and seventh aspects of this invention and FIGS. 22 thru 32 to the eighth thru fifteenth aspect of this invention. Each one of the aspects of the invention may be considered to be an invention in its own right but the various aspects of this invention are intended to be combined in order to manufacture electronic circuits and, in particular, optoelectronic circuits.

First Aspect.

FIG. 1a represents the conventional stacking of semiconductor diode lasers well known to the expert. Thus we can distinguish the electrical and optical confinement layers 101, the confinement layers 105 of the optical cavity and the emitting layer 104 where the laser effect is produced. The injection of carriers is obtained by realizing two contacts 100, one of which is on the front surface and the other via the rear surface, generally these two contacts inject the holes and the electrons respectively that are going to be re-combined in the active emission area 104 to emit light. The variant shown in FIG. 1b concerns the same conventional laser structure where the contact on the rear surface is mounted on the surface by additional etching steps. These two structures are realized in the form of chips that can be manipulated.

FIG. 2a proposes the schematic diagram of the invention and its application in the case of a side emitting diode laser where the contacts are on the front surface and rear surface, FIG. 2b, and on the front surface only, FIG. 2c.

The schematic diagram of the invention, FIG. 2a, is represented in its final form. It is clear that the process of realization itself contributes to the original nature of the assembly and it shall be described later. The invention comprises the hybridizing by flipping with beads of solder 107 (technique known as “flip chip”) an optical or electronic component 108 on a semiconductive base 106, for example in silicon, where the interconnection lines needed for the operation of the component 108 are already integrated. Other types of base are possible, such as: silicon carbide, aluminum nitride, gallium nitride. In a higher level of complexity, the diode laser's current and modulation generator may be integrated on the single heat sink mounted.

In the same way, one at least of the dissipation bases could integrate the electronics allowing the diode laser to operate and/or be monitored.

The beads of solder 107 provide the electrical connections and allow the heat to be drained from the component in operation towards the semiconductive substrate that constitutes a good heat sink. It is clear to the expert that the more beads 107 there are, the larger the contact surface will be and the more effective the draining of heat to the substrate 106. A process of coating with a polymer element that is a heat conductor and also an electrical insulator allows the thermal resistance to be improved and the assembly to be solidified. The rear surface of the component 108 can thus be used for integrating, either by deposition or also by mounting, a second heat sink 109 realized in metallic materials (Gold, Copper, for example) or recognized for their excellent thermal conduction properties (silicon carbide, aluminum nitride, gallium nitride). The electrical connectivity of the lasers is thus provided at the same time as the heat sinks, either directly on the rear surface or by mounting a material with high thermal conductivity.

This assembly and process may be applied directly to the assembly of diode lasers covering the range of wavelengths from 0.6 μm to 2 μm according to the two configurations (front and rear surface contacts, FIG. 1a, and contacts on the front surface, FIG. 1b). FIG. 2b shows a configuration example. In this particular case, the second heat sink is mounted and soldered by beads 107. It also allows the electrical connection to be carried out on the rear surface of the diode laser 112 via beads 109 connected to the power lines of the component integrated on the semiconductor substrate 106. A second coating 110 enables the assembly to be solidified and also the thermal contact between 109 and 112 to be improved.

In the particular case of a diode laser having the two contacts on the front surface, the assembly is then very close to the schematic diagram. The second heat sink mounting may in this case be realized either

by direct electrolytic growth of the metal on the rear surface of the component over thicknesses greater than 50 μm

by mounting a metal block glued by an adhesive with good thermal conduction properties.

The heat sink may thus be completely integrated in the housing or be the housing, which increases the heat exchange surface noticeably.

It is this second particular case which is shown in FIG. 2c.

FIG. 3 proposes and details an example of manufacturing process modulable according to the geometric and topological characteristics of the laser used. It is applied to side emitting lasers with contacts n and p on the front surface as well as to vertical emitting lasers known as VCSELs. The starting substrate 106, FIG. 3a, integrates the electrical lines for the laser's power supply and the solder bead coupling contacts for the connection. It can also comprise other components necessary for the proper operation of the emitting laser considered (passive capacitive elements, inductive elements, resistors, photodiodes, pilot circuit, etc). This substrate may be realized in silicon, the most commonly used material, or else in different semiconductive materials, for example aluminum nitride (AlN), gallium nitride (GaN), or diamond.

Initially, all the solder beads 107 shall be realized, FIG. 3b, by conventional techniques. For preference, these beads shall be of a small size, about 20 μm in diameter, so as to be able to position the maximum number possible. These techniques involve different technological steps of applying resin, lithography, opening up contact areas, depositing fusible material (for example, indium), forming beads. The side or vertical emitting laser component is then positioned and soldered by heat treatment to the network of beads, which thus ensures the electrical connection and the thermal contact between the laser and the semiconductive heat sink base, FIG. 3c. The component is then coated with a polymer that is a heat conductor and electrical insulator in such a way 111 as to ensure a mechanical hold and also a thermal contact as large as possible for the laser chip. It is noted that following the soldering process there can be a chip self-alignment effect. The realization of the solder beads and also the coating methods are described in the processes relating to patents U.S. Pat. No. 5,496,769 and FR9615348.

After this a resin is applied 114, a standard process in microelectronics. Polishing the assembly makes it possible to smooth and free the rear surface of the component, FIG. 3e. The polishing also allows removal of all or part of the substrate on which the laser was realized and which is usually of GaAs or InP material, considered to be poor thermal conductors. This is especially recommended in the case of vertical emitting lasers. Following this step, a metal coupling deposition 115 is realized on the substrate assembly, FIG. 3f, enabling the subsequent electrolytic deposition of the same metal or another metal. At this stage, the size of the heat sink can be defined by the conventional techniques of resin application and photolithography, FIG. 3g. The deposition is then realized on thicknesses ranging from tens of microns to 100 μm, FIG. 3h. The steps shown in FIGS. 3i, 3j and 3k comprise eliminating the various resin layers by solvents, thus freeing the whole of the device stack. These steps are technological steps known to the expert.

The manufacturing process is similar in the case of a vertical emitting laser. It nevertheless presents the difference that we are going to specify. Thus, it is necessary to realize a hole in the starting substrate allowing light to be emitted downwards without absorption in the substrate 106. The final assembly is shown in FIG. 4. This hole may serve to guide the fiber. This particularity may be avoided if the starting substrate is transparent to the laser's emitting wavelength.

This type of assembly is of particular interest for laser applications needing to generate high powers and also for operations at strong intensity modulation (for example operating diode lasers at a strong intensity modulation of 10 GHz and above) without having to use a Peltier-type external heat sink. In addition, in this component flip-chip configuration, the substrate may be removed entirely and replaced by a material with a high power of heat transfer. Thus, the heat is drained to the closest semiconductive junction. Indeed it is difficult to push conventional thinning beyond a substrate thickness of 100 μm without posing manipulation problems.

The invention can also be directly applied to power electronic devices such as bipolar transistors, field-effect transistors which are components possessing two contacts on the front surface and whose architecture and materials are compatible with the process described.

Second and Third Aspects.

FIGS. 5 and 6 show a substrate 501 previously fitted with metallized contacts 511 (see FIGS. 8 and 12) allowing various electronic and optoelectronic components to be mounted by means of flip-chip technology, in particular an optoelectronic component 502, its control circuit 503 and one or more electronic components (integrated circuits) 504 (in the figures, one single component 504 is shown) needed to control the optoelectronic component 502 or to convert the signal detected if the component is a detector, for example a photodiode, as well as the passive electronic components needed for their operation (not shown).

The optoelectronic component 502 is, for example, a VCSEL vertical emitting laser, for emitting a light signal in an optical fiber 507, or a PIN or avalanche photodiode, for detecting and receiving a light signal coming from an optical fiber 507.

The substrate 501 can be realized in various materials (Silicon, Alumina, Quartz, etc) compatible with realizing, on at least one of its surfaces, conductive tracks (not shown) adapted to propagate a microwave electrical signal. On this substrate, metallized contacts can be realized on which a fusible material is deposited, for example indium, which is likely during re-fusing to re-form itself into beads of a controlled diameter, typically between 5 μm and 500 μm. This is the microbeading process known under the name “flip-chip”.

In both cases, laser and photodiode, the optoelectronic component 502 is equipped with metallized contacts coinciding with the position of the beads of the substrate 501. The use of a flip-chip type of mounting is motivated by this technology's good microwave performance and its properties of self-alignment for the component 502, thus allowing its position to be controlled with respect to the hole 510 guiding the optical fiber 507. Because of this, this invention realizes a passive alignment of the optical fiber 507 and the optoelectronic component 502 in the plane of the substrate 501. The substrate 501, shown in a front view in FIG. 6, is pierced with a through hole 510 located facing the light emitting area of the laser or the reception area of the photodiode.

The hole 510 realized in the substrate 501 can be obtained by different processes, such as dry etching or laser drilling. The shape of the hole 510 is not necessarily circular: it may be any geometric shape which can enclose a circle with the diameter of the optical fiber to be inserted, typically 125 to 130 μm (see FIG. 11).

In a fiber carrier or rod 506, the optical fiber 507, for example silica, is held in place by gluing or any other means of fixing (brazing, soldering, glass-glass sealing, etc). One of the surfaces of the fiber carrier 506 is in contact with the surface of the substrate 501 opposite the surface hosting the optoelectronic component 502.

This fiber carrier or rod 506 is shown in cross-section view in FIGS. 7 and 8. It is comprised of a capillary tube 508, for example ceramic, containing the optical fiber 507, the capillary tube 508 being inserted in an external body 509 which may be metal or any other material. The part of the fiber carrier 506 in contact with the optical fiber 507 is the capillary tube 508, provided with a hole whose diameter is close to the external diameter of the optical fiber 507. The parts comprising the fiber carrier 506 may be fixed to each other in different ways, for example by press-fitting, gluing or soldering.

The optical fiber 507 may be monomode or multimode, depending on the application envisaged and the emitting wavelength used. One part 512 of the optical fiber projects from the fiber carrier or rod 506 for a length L determined beforehand knowing the changes to the coupled power of the laser in the fiber or of the fiber in the photodiode, depending on the gap between these two components and the thickness of the substrate 501. The length of projection L can be controlled to a very small margin, for example by using a process of cleaving or cutting the optical fiber 507 by laser, or a process of polishing the end of the optical fiber 507.

FIG. 8 shows the definitive configuration of the optical module once the fiber carrier or rod 506 is assembled to the substrate 501, the part 512 of the optical fiber 507 that projects from the fiber carrier 506 being inserted in the hole 510 until the fiber carrier and substrate 501 are brought into contact. The distance between the active area of the optoelectronic component and the substrate is determined by the height h of the fusible beads 511, known accurately. The residual gap e between the optoelectronic component and the optical fiber 507 thus has the value (see FIG. 12):
e=s+h−L

Thus, the length of projection L is defined so that, once the optical fiber 507 has been placed in the hole 510 and the fiber carrier 506 is touching the surface of the substrate 501 opposite the mounting pad for the optoelectronic components, the residual gap e between the active surface of the optoelectronic component 502 and the cleaved end of the optical fiber 507 corresponds to the looked-for rate of coupling of the light. The looked-for coupling rate may be voluntarily limited in order not to exceed coupled power levels in the fiber incompatible with the levels of ocular safety required by the standards in force.

Because of this, this invention realizes a passive alignment of the optical fiber 507 and the optoelectronic component 502 in the direction perpendicular to the plane of the substrate 501.

The space of thickness e separating the optical fiber 507 and the optoelectronic component 502 can, moreover, be filled with an adhesive or another transparent material (see FIG. 12) whose optical index is close to that of the optical fiber 507, for example approximately 1.5 for certain glasses or silicas.

The end of the optical fiber 507 may also be equipped with a microlens (not shown) and/or be covered with an antireflection treatment, so as to optimize the rate of coupling of the optoelectronic component and the optical fiber 507.

For preference, the operations of preparing the substrate 501 and mounting the optoelectronic component 502 and electronic components 503 and 504 are carried out collectively on one plate (wafer) of one single material, and afterwards this plate is cut to the dimensions of an individual substrate 501. In this way, the manufacturing costs are reduced by a collective approach.

FIG. 9 shows that this invention, the characteristics of which are described above for one single optoelectronic component 502, may easily be utilized in what are known as parallel optics applications, in which several vertical emitting lasers or several photodiodes 522 need to be aligned simultaneously to a band of optical fibers 540, typically numbering 4, 8 or 12.

To this end, the band of optical fibers 540 is placed in a multi-fiber rod or fiber carrier 526 or in a block of what are known as “V-grooves” (see FIG. 10) and a collective cleaving of the optical fibers is carried out such that each optical fiber projects from the fiber carrier by a defined length L. With regard to the substrate 521, this is pierced by a number of holes 530, the number of which corresponds to the number of optoelectronic components 522 to be coupled to the band of optical fibers 540.

For example, the optical fibers 540, once assembled in the fiber carrier 526, are spaced typically at a distance of 250 μm and are guided by the holes 530 pierced in the substrate 521, opposite which an equal number of optoelectronic components, for example vertical emitting lasers or photodiodes, have been respectively mounted by “flip-chip”.

The set of optoelectronic components may be arranged in a strip or in a two-dimensional matrix.

For preference, the holes 530 are arranged on lines, each of which comprises at least three holes 530.

FIG. 10 shows, in cross-section, the band of optical fibers 540 and the fiber carrier 526 comprised of at least one (here two) part 535 bearing at least one groove 536 in which one optical fiber 527 may be at least partially inserted. Each optical fiber 527 is blocked in position in the fiber carrier 526 by tightening, one against another, the parts 535 or, if there is only one part 535 comprising grooves, by tightening this part 535 against a flat part without grooves, traditionally known as a “counterplate”.

FIG. 11 shows, in cross-section, a hole 510 or 530 utilized in the embodiments shown in FIGS. 5 thru 10. This hole has a shape where the diameter of the circle inscribed is greater than the diameter of an optical fiber 507 or 527 and where the circle inscribed has, with the said shape, three points of contact forming a triangle, for preference noticeably equilateral. In this way, the optical fiber may be precisely positioned in the hole while leaving room so that, by capillary action, adhesive with an optical index close to that of the optical fiber might fill the space between the edges of the hole and the fiber, since the distance between the fiber and the edges of the hole is variable over the circumference of the optical fiber.

FIG. 12 shows, in cross-section, an optical coupling between an optical fiber 507 or 527 and an optoelectronic component, 502 or 522.

The end of the optical fiber is cleaved so as to optimize the coupling of the light. This cleaving is realized, in the embodiment shown, with an angle of between 4 and 8° which limits the secondary reflections at the optical fiber interface.

The residual gap e between the optical fiber and the optoelectronic component is, in the embodiment shown, filled with a transparent material 550, for example an ultraviolet-curable adhesive, the optical index of which is close to that of the optical fiber, so as to reduce the reflection of light on the fiber.

The residual gap e between the optoelectronic component and the optical fiber 507 has the value
e=s+h−L where:

L is the length of the part of the optical fiber projecting from the fiber carrier,

h is the distance between the active area of the optoelectronic component and the substrate, equal to the height h of the fusible beads, known accurately, and

s is the thickness of the substrate bearing the hole in which the optical fiber is inserted.

FIG. 13 shows, in the form of a logical diagram, steps utilized in a particular embodiment of the process that is the subject of the present invention.

During a step 600, you determine an optical coupling rate that you wish to obtain in a repeated and accurate way between an optical fiber and an optoelectronic component and you define the gap e between these components corresponding to this coupling rate and the value of the length L of the part of the optical fiber projecting from the fiber carrier, taking into account the values of the thickness s of the substrate and the height h of the fusible beads.

During a step 605, a substrate is prepared and electronic and optoelectronic components are mounted on one plate (wafer) of one single material, utilizing a “flip-chip” process with beads of diameter h.

In particular, you mount one optoelectronic component, one control circuit for the driver, and electrical tracks linked on the one hand to the control circuit and, on the other hand, to the optoelectronic component and allowing a microwave signal to be propagated between said driver's control circuit and said optoelectronic component.

The step of mounting via a “flip-chip” method comprises a step of mounting metallized contacts on the substrate 606 and a step of depositing a fusible material on said metallized contacts.

The step of mounting via a “flip-chip” method comprises a step 607 of mounting, on the optoelectronic component, metal contacts corresponding to the position of the substrate's beads.

The mounting step comprises a step of placing opposite each other 608 the components' metallized contacts and metallized contacts on the substrate.

Finally, the mounting step comprises a step of re-fusing 609 the fusible material during which the fusible material takes the form of a bead of a controlled diameter.

During a step 610, the piercing of each hole needed for the passage of an optical fiber is carried out, in a substrate with a thickness s. Each hole is calibrated and passes through said substrate, and is facing an optoelectronic component and is intended to guide an optical fiber in the direction of said optoelectronic component.

During an optional step 615, the plate is cut to the dimensions of an individual substrate.

During a step 620, at least one optical fiber is inserted in a fiber carrier and these two elements are secured.

During a step 625, each optical fiber is cleaved, so that the part of the fiber projecting from the fiber carrier has a length L. The cleaving may be carried out at an angle with respect to the axis of the optical fiber, so as to limit the secondary reflections.

During a step 630, a fiber fixed in a fiber carrier is inserted, in at least one hole.

During a step 635, the optical fiber and the fiber carrier are fixed to the substrate, for example by gluing or brazing, facing an optoelectronic component, said fiber carrier at the end of the assembly process touching the substrate surface opposite the mounting pad of the optoelectronic component.

In this way, the gap between the active surface of the optoelectronic component and the end of the optical fiber thus corresponds to the pre-defined coupling rate.

For fixing the optical fiber, you use, for example, an adhesive with an optical index close to that of the optical fiber which, by capillary action, fills the space between the optical fiber and the hole.

During an optional step 640, the gap between the active surface of the optoelectronic component and the end of the optical fiber is filled with a transparent material whose optical index is close to that of the optical fiber.

Fourth and Fifth Aspects.

FIG. 14 shows an optoelectronic device 700 comprising a main substrate 705 on which is mounted a host substrate 707 bearing a VCSEL laser 710 whose effective emitting surface 715 is placed facing the main substrate 705. A hole 720 is realized across from the active surface of the VCSEL laser 710 to effect an optical coupling of the laser and an optical fiber 725 inserted in the hole 720.

The main substrate 705 can be realized in various materials (Silicon, Alumina, Quartz, etc) compatible with realizing, on at least one of its surfaces, conductive tracks (not shown) adapted to propagate a microwave electrical signal. On this main substrate 705, metallized contacts are realized on which a fusible material is deposited that is likely during re-fusing to re-form itself into beads 717 of a controlled diameter, typically between 20 μm and 500 μm. This is the microbeading process known under the name “flip-chip”.

The host substrate 707 is thus linked to the main substrate 705 via metallization allowing a “flip-chip”-type of positioning by means of fusible metal (Indium, AuSn or other eutectic alloy) beads 717, which are themselves placed on metallized contacts that have been realized on the main substrate 705. The host substrate 707 of the laser 710 is equipped with metallized contacts coinciding with the position of the beads 717 of the main substrate 705.

The diameter of the fusible beads 717 is chosen according to the VCSEL's final height. The beads 717 provide both the mechanical positioning and the electrical connection of the photodiode to other components borne by the main substrate 705.

The use of a flip-chip type of mounting is motivated by this technology's good microwave performance and its properties of self-alignment for the host substrate 707 of the laser 710, thus allowing its position to be controlled with respect to the main substrate 705.

The hole 720 realized in the main substrate 705 can be obtained by different processes, such as dry etching or laser drilling. The shape of the hole 720 is not necessarily circular: it may be any geometric shape which can enclose a circle with the diameter of an optical fiber 725 to be inserted, typically 125 to 130 μm.

A photodiode 730 is manufactured separately from the VCSEL laser 710 and it is then mounted, with a substrate 732 on which it is borne, via the same flip-chip technology utilizing the microbeads 734, the active area generally being on the front surface, which means it has to be turned over.

The photodiode 730 is positioned, on the main substrate 705, facing the surface of the VCSEL laser 710 opposite to its effective emitting surface 715. In the embodiment shown in FIG. 14, the host substrate 707 is absorbent in the emitting wavelength of the VCSEL laser 710. So that the photodiode 730 picks up a part of the light emitted by the VCSEL laser 710 via its surface opposite to the effective emitting surface 715, the substrate 707 is provided with an opening 735 on this opposite surface, an opening by which the photodiode 730 receives a part of the light emitted by the laser 710.

For example, the opening 735 is effected by piercing the host substrate 707 after the epitaxial growth of the VCSEL laser 710.

The realization of the hole in the rear surface of the VCSEL laser 710 is performed after the laser 710 is mounted via flip-chip on the main substrate 705. In a variant, a coating step is added, which makes it possible to harden or make solid the whole host substrate—main substrate assembly and to continue with traditional technological operations still at the wafer scale on the mounted components. Once these operations have been carried out, the photodiode 730 is mounted over the laser 710. The two components are thus stacked one on top of the other.

Once positioned and connected by means of beads 734, the photodiode 730 detects the candlepower emitted by the surface of the VCSEL 710 opposite the effective emitting surface.

A monitoring and regulation circuit (not shown) receives the signal emitted by the photodiode 730 and, according to its intensity, modifies the electrical power supplied to the laser 710, in such a way that the maximum candlepower emitted by this laser 710 remains noticeably constant over time, to compensate for the aging of the laser 710.

In a fiber carrier or rod 740, the optical fiber 725, for example silica, is held in place by gluing or any other means of fixing (brazing, soldering, etc). One of the surfaces of the fiber carrier 740 is in contact with the surface of the main substrate 705 opposite the surface hosting the host substrate 707 of the laser 710.

This fiber carrier or rod 740 is comprised of a capillary tube, for example ceramic, containing the optical fiber 725, the capillary tube being inserted in an external body that may be of metal or any other material. The optical fiber 725 may be monomode or multimode, depending on the application envisaged and the emitting wavelength used. One part of the optical fiber 725 projects from the fiber carrier or rod 740 for a length L determined beforehand knowing the changes to the coupled power of the laser 710 in the fiber 725, depending on the gap between these two components and the thickness of the main substrate 705. The length of projection L can be controlled to a very small margin, for example by using a process of cleaving or cutting the optical fiber 725 by laser, or a process of polishing the end of the optical fiber 725.

Thus, the length of projection L is defined so that, once the optical fiber 725 has been placed in the hole 720 and the fiber carrier 740 is touching the surface of the main substrate 705 opposite the mounting pad of the host substrate 707 of the laser 710, the residual gap e between the active surface of the laser 710 and the cleaved end of the optical fiber 725 corresponds to the looked-for rate of coupling of the light. The looked-for coupling rate may be voluntarily limited in order not to exceed coupled power levels in the fiber incompatible with the levels of ocular safety required by the standards in force.

Because of this, this invention realizes a passive alignment of the optical fiber 725 and the laser 710 in the direction perpendicular to the plane of the main substrate 705.

The space of thickness e separating the optical fiber 725 and the laser 710 can, moreover, be filled with an adhesive or another transparent material whose optical index is close to that of the optical fiber 725, for example approximately 1.5 for certain glasses or silicas.

The optical fiber 725 may also be equipped with a microlens at the end (not shown), so as to optimize the coupling rate of the laser 710 and the optical fiber 725.

For preference, the operations of preparing the main substrate 705 and mounting the host substrate 707 of the laser 710 and electronic components are carried out collectively on one plate (wafer) of one single material, and afterwards this plate is cut to the dimensions of an individual main substrate 705 (see FIG. 16). In this way, the manufacturing costs are reduced by a collective approach.

FIGS. 15A and 15B show, in the form of a logical diagram, steps utilized in a particular embodiment of the process that is the subject of the present invention.

During a step 800, you determine the candlepower that you wish to receive on the photodiode, during the life of the VCSEL laser.

During a step 801, a VCSEL laser is prepared by epitaxy on a host substrate.

During a step 802, the main substrate is prepared.

During a step 803, the piercing of a hole necessary for the passage of an optical fiber is carried out, in the main substrate. The hole is calibrated, it passes through the main substrate, it is facing a VCSEL laser and it is intended to guide an optical fiber in the direction of the effective surface of the VCSEL laser.

Then, step 804, electronic and optoelectronic components are mounted on one plate (wafer) of one single material, utilizing a “flip-chip” process with beads of fusible material.

In particular, you mount the host substrate bearing the VCSEL laser, a control circuit and electrical tracks linked on the one hand to the control circuit and, on the other hand, to the laser, which allow a microwave signal to be propagated between said driver's control circuit and said laser.

The step of mounting via a “flip-chip” method comprises a step of mounting metallized contacts on the main substrate 805 and a step of depositing a fusible material on said metallized contacts.

The step of mounting via a “flip-chip” method also comprises a step 806 of mounting, on the host substrate bearing the laser, metal contacts corresponding to the position of the main substrate's beads.

The mounting step comprises a step of placing opposite each other 807 the host substrate's metallized contacts and metallized contacts on the main substrate.

Finally, the mounting step comprises a step of re-fusing 808 the fusible material during which the fusible material takes the form of a bead of a controlled diameter.

During a step 809, the host substrate is pierced on the surface opposite to the VCSEL laser's effective surface until the laser's emitting layer is reached. The piercing is, for example, carried out by a method of dry etching, laser drilling or mechanical machining.

To pierce the host substrate of the VCSEL laser locally, it may be useful for this host substrate to be thinned so as to allow a photolithography step to be carried out. A pattern is thus delineated on top of the laser's emitting area and the material is locally etched. The dimensions of this hole are defined in such a way as not to isolate the area where current is injected. A method of selective etching allows the etching to be stopped at the first Bragg mirror layers (aluminized alloy).

During a step 810, electronic and optoelectronic components are mounted on one plate (wafer) of one single material, utilizing a “flip-chip” process with beads of fusible material.

In particular, you mount the substrate bearing the photodiode, a control circuit and electrical tracks linked on the one hand to the control circuit and, on the other hand, to the photodiode, which allow a microwave signal to be propagated between said control circuit and said photodiode. The step of mounting 810, via a “flip-chip” method, comprises a step of mounting metallized contacts on the main substrate, a step of depositing a fusible material on said metallized contacts, a step of mounting, on the photodiode's substrate, metal contacts corresponding to the position of the main substrate's beads, a step of placing opposite each other the metallized contacts of the photodiode's substrate and metallized contacts on the main substrate, and a step of re-fusing fusible material during which the fusible material takes the form of a bead of a controlled diameter.

At the end of the step 810, the photodiode is thus facing the host substrate's piercing and the photodiode is linked to the main substrate's conductive lines. The monitoring and regulation photodiode is thus positioned in such a way that it covers the VCSEL laser and is placed in the beam emitted by the VCSEL laser, on its surface opposite to its effective surface. Because of this, the beam extracted via the rear of the VCSEL laser is converted into electric current by the photodiode and may thus be used to detect a possible VCSEL malfunction and/or regulate its average power.

During a step 811, an optical fiber is inserted in a fiber carrier and these two elements are secured.

During a step 812 (FIG. 15B), the optical fiber is cleaved, so that the part of the fiber projecting from the fiber carrier has a length L. The cleaving may be carried out at an angle with respect to the axis of the optical fiber, to limit the secondary reflections.

During a step 813, a fiber fixed in a fiber carrier is inserted, in at least one hole.

During a step 814, the optical fiber carrier is fixed to the main substrate, for example by gluing or brazing, facing a laser, said fiber carrier at the end of the assembly process touching the main substrate surface opposite the mounting pad of the host substrate on the main substrate.

For fixing the optical fiber, you use, for example, an adhesive with an optical index close to that of the optical fiber which, by capillary action, fills the space between the optical fiber and the hole.

During an optional step 815, the gap between the active surface of the optoelectronic component and the end of the optical fiber is filled with a transparent material whose optical index is close to that of the optical fiber.

During the operation of the VCSEL laser, step 816, the candlepower emitted by this laser is measured with the photodiode placed on the same host substrate, and this power is controlled, step 817, by regulation, according to techniques known per se.

FIG. 16 shows a variant of the invention adapted to the case where the respective power of several VCSEL lasers 710, each integrated on a host substrate 707, must be monitored and regulated. Several holes 735 are thus realized opposite the rear emitting areas of the lasers 710, and the substrates of the photodiodes 710 comprising as many distinct photosensitive areas as there are VCSEL lasers 710 are positioned, in the same way as above.

FIG. 16 shows that this invention, the characteristics of which are described above for one single laser 710, may easily be utilized in what are known as parallel optics applications, in which several vertical emitting lasers 710 need to be aligned simultaneously to a band 775 of optical fibers 725, typically numbering 4, 8 or 12.

To this end, the band of optical fibers 725 is placed in a multi-fiber rod or fiber carrier 775 or in a block of what are known as “V-grooves” and a collective cleaving of the optical fibers 725 is carried out such that each optical fiber 725 projects from the fiber carrier by a defined length L. With regard to the common main substrate 755, this is pierced by a number of holes 750, the number of which corresponds to the number of lasers 710 to be coupled to the optical fibers 725.

In order to simultaneously monitor several VCSEL lasers 710 packaged in one single optoelectronic housing, for what is known as a parallel optics application, the operations described in FIGS. 15A and 15B are realized for each VCSEL laser 710, these VCSEL lasers 710 then being assembled on the common main substrate 755, and a monitoring and regulation photodiode 730 is positioned on top of each VCSEL laser, thanks to a fusible bead technology (“flip chip”).

This problem can also be handled collectively, not by using discrete or separated VCSEL substrates, but by using a host substrate bearing several VCSELs 710 in a line or in a matrix. The processes mentioned above are collective and can thus be applied simultaneously on all the lasers 710. In this case, you use, for monitoring the power, respectively a strip or a matrix of photodiodes 730, positioned and fixed on top of the strip of VCSELs by use of a fusible bead technology.

In a variant to the embodiments shown in FIGS. 14 to 16, instead of carrying out a piercing of the host substrate so as to insert a photodiode, a complete removal of the host substrate is effected, this variant only being possible if the VCSEL laser component 710 allows it. Indeed, as the heat of the laser is dissipated via its host substrate, only a component specifically designed for this application would be able to continue working after such a treatment. In this variant, after the VCSEL laser's substrate is removed, a material allowing the heat to be dissipated and allowing the light emitted by the laser to pass can be mounted on the VCSEL laser before the photodiode is mounted.

The embodiments described above with respect to FIGS. 14 to 16 are adapted to the cases where the host substrate is absorbent in the emitting wavelength of the VCSEL laser. For example, in the case of GaAs, the material is transparent at 1310 nm while it absorbs at 850 nm.

On the contrary, the embodiments shown in FIGS. 17 and 18 are adapted to the case where the host substrate is, at least partially, transparent to the VCSEL laser's emitting wavelength.

In this case, following step 804, a step 904 is performed of partial removal of the host substrate 745 by a mirror-quality polishing. Then, during a step 905, an antireflection treatment is applied to the polished surface of the host substrate 745, so as to prevent a loss of light by reflection or diffusion. Then a substrate bearing the photodiode 730 is mounted on the main substrate, during step 905. Then, steps 811 to 817 are carried out.

The thinning of the host substrate 745 on the rear surface of the VCSEL laser 710 is carried out after the mounting by flip chip of the laser.710 on the main substrate 705. In a variant, a coating step is added, which makes it possible to harden or make solid the whole host substrate—main substrate assembly and to continue with traditional technological operations still at wafer scale on the mounted components. Once these operations have been carried out, the photodiode 730 is mounted over the laser 710. The two components are thus stacked one on top of the other.

Obviously, the embodiment shown in FIGS. 17 and 18 can be adapted to the case of a plurality of lasers and a plurality of photodiodes, as described, above, with respect to FIG. 16 for the first embodiment shown in FIGS. 14 and 15.

Sixth and Seventh Aspects.

FIG. 19 shows an optoelectronic device 1000 comprising a main substrate 1005 on which is mounted a host substrate 1007 bearing a VCSEL laser 1010 whose effective emitting surface 1015 is placed facing the main substrate 1005. A hole 1020 is realized across from the active surface of the VCSEL laser 1010 to effect an optical coupling of the laser and an optical fiber 1025 inserted in the hole 1020.

The main substrate 1005 can be realized in various materials (Silicon, Alumina, Quartz, etc) compatible with realizing, on at least one of its surfaces, conductive tracks (not shown) adapted to propagate a microwave electrical signal. On this main substrate 1005, metallized contacts are realized on which a fusible material is deposited that is likely during re-fusing to re-form itself into beads 1017 of a controlled diameter, typically between 20 μm and 500 μm. This is the microbeading process known under the name “flip-chip”.

The host substrate 1007 is thus linked to the main substrate 1005 via metallization allowing a “flip-chip”-type of positioning by means of fusible metal (Indium, AuSn or other eutectic alloy) beads 1017, which are themselves placed on metallized contacts that have been realized on the main substrate 1005. The host substrate 1007 of the laser 1010 is equipped with metallized contacts coinciding with the position of the beads 1017 of the main substrate 1005.

The diameter of the fusible beads 1017 is chosen according to the VCSEL's final height. The beads 1017 provide both the mechanical positioning and the electrical connection of the photodiode to other components borne by the main substrate 1005.

The use of a flip-chip type of mounting is motivated by this technology's good microwave performance and its properties of self-alignment for the host substrate 1007 of the laser 1010, thus allowing its position to be controlled with respect to the main substrate 1005.

The hole 1020 realized in the main substrate 1005 can be obtained by different processes, such as dry etching or laser drilling. The shape of the hole 1020 is not necessarily circular: it may be any geometric shape which can enclose a circle with the diameter of an optical fiber 1025 to be inserted, typically 125 to 130 μm.

A photodiode 1030 is manufactured directly on the main substrate 1005. For example, in the case where the main substrate 1005 is silicon Si, the photodiode 1030 is for preference a metal-semiconductor-metal type. In the case where the main substrate 1005 is gallium arsenide AsGa, the photodiode 1030 is for preference a PIN type. In the case where the main substrate 1005 is quartz, the photodiode 1030 is mounted.

In all cases, the photodiode 1030 is positioned facing the effective surface of the laser 1010, close to the direct optical path linking the laser 1010 to the optical fiber 1025, i.e., in the embodiment shown in FIGS. 19 thru 21, close to the hole 1020. In the case of a quartz main substrate, it is noted that it is not necessary to provide a hole because the quartz is transparent to the wavelengths emitted by the laser 1010.

Optionally, the photodiode 1030 is linked to a low noise microamplifier and at least one low-pass filter (not shown). In the case where the power supplied by the photodiode 1030 is low, an amplifier may be provided either on the main substrate 1005, or on a separate printed circuit.

For preference, the photodiode 1030 is given an antireflection treatment over its whole surface facing the laser 1010.

On the rear surface of the VCSEL laser 1010 the mounting of a mirror 1035 is effected. This mirror is mounted by techniques known in prior art. It serves to increase the power emitted by the laser 1010 in the direction of the optical fiber 1025 and, as a result, of the photodiode 1030.

Thus, the photodiode 1030 detects the candlepower emitted by the effective surface of the VCSEL laser 1010 without any optical component being interposed on the optical path going from the laser 1010 to the photodiode 1030, with the possible exception of a convex lens concentrating the light beam coming from the laser 1010 on the inbound surface of the optical fiber 1025.

A monitoring and regulation circuit (not shown) receives the signal emitted by the photodiode 1030 and, according to its intensity, modifies the electrical power supplied to the laser 1010, in such a way that the maximum candlepower emitted by this laser 1010 remains noticeably constant over time, to compensate for the aging of the laser 1010.

In a fiber carrier or rod 1040, the optical fiber 1025, for example silica, is held in place by gluing or any other means of fixing (brazing, soldering, etc). One of the surfaces of the fiber carrier 1040 is in contact with the surface of the main substrate 1005 opposite to its surface hosting the host substrate 1007 of the laser 1010.

This fiber carrier or rod 1040 is comprised of a capillary tube, for example ceramic, containing the optical fiber 1025, the capillary tube being inserted in an external body that may be of metal or any other material. The optical fiber 1025 may be monomode or multimode, depending on the application envisaged and the emitting wavelength used. One part of the optical fiber 1025 projects from the fiber carrier or rod 1040 for a length L determined beforehand knowing the changes to the coupled power of the laser 1010 in the fiber 1025, depending on the gap between these two components and the thickness of the main substrate 1005. The length of projection L can be controlled to a very small margin, for example by using a process of cleaving or cutting the optical fiber 1025 by laser, or a process of polishing the end of the optical fiber 1025.

Thus, the length of projection L is defined so that, once the optical fiber 1025 has been placed in the hole 1020 and the fiber carrier 1040 is touching the surface of the main substrate 1005 opposite the mounting pad of the host substrate 1007 of the laser 1010, the residual gap e between the active surface of the laser 1010 and the cleaved end of the optical fiber 1025 corresponds to the looked-for rate of coupling of the light. The looked-for coupling rate may be voluntarily limited in order not to exceed coupled power levels in the fiber incompatible with the levels of ocular safety required by the standards in force.

Because of this, this invention realizes a passive alignment of the optical fiber 1025 and the laser 1010 in the direction perpendicular to the plane of the main substrate 1005.

The space of thickness e separating the optical fiber 1025 and the laser 1010 can, moreover, be filled with an adhesive or another transparent material whose optical index is close to that of the optical fiber 1025, for example approximately 1.5 for certain glasses or silicas.

The optical fiber 1025 may also be equipped with a microlens at the end (not shown), so as to optimize the coupling rate of the laser 1010 and the optical fiber 1025.

For preference, the operations of preparing the main substrate 1005 and mounting the host substrate 1007 of the laser 1010 and electronic components are carried out collectively on one plate (wafer) of one single material, and afterwards this plate is cut to the dimensions of an individual main substrate 1005 (see FIG. 21). In this way, the manufacturing costs are reduced by a collective approach.

FIGS. 20A and 20B show, in the form of a logical diagram, steps utilized in a particular embodiment of the process that is the subject of the present invention.

During a step 1100, you determine the candlepower that you wish to receive on the photodiode, during the life of the VCSEL laser.

During a step 1101, a VCSEL laser is prepared by epitaxy on a host substrate.

During a step 1102, the main substrate is prepared.

During a step 1103, the piercing of a hole necessary for the passage of an optical fiber is carried out, in the main substrate thickness. The hole is calibrated, passes through the main substrate, is facing a VCSEL laser and is intended to guide an optical fiber in the direction of the effective surface of the VCSEL laser.

Then, step 1104, electronic and optoelectronic components are mounted on one plate (wafer) of one single material, utilizing a “flip-chip” process with beads of fusible material.

In particular, you mount the host substrate bearing the VCSEL laser, a control circuit and electrical tracks linked on the one hand to the control circuit and, on the other hand, to the laser, which allow a microwave signal to be propagated between said driver's control circuit and said laser.

The step of mounting via a “flip-chip” method comprises a step of mounting metallized contacts on the main substrate 1105 and a step of depositing a fusible material on said metallized contacts.

The step of mounting via a “flip-chip” method also comprises a step 1106 of mounting, on the host substrate bearing the laser, metal contacts corresponding to the position of the main substrate's beads.

The mounting step comprises a step of placing opposite each other 1107 the host substrate's metallized contacts and metallized contacts on the main substrate.

Finally, the mounting step comprises a step of re-fusing 1108 the fusible material during which he fusible material takes the form of a bead of a controlled diameter.

Electrical tracks are linked on the one hand to the control circuit and, on the other hand, to the photodiode, which allow a microwave signal to be propagated between said control circuit and said photodiode.

At the end of the step 1108, the photodiode is thus facing the effective surface of the laser 1010 and close to the axis of the optical fiber. The monitoring and regulation photodiode 1030 is thus positioned in such a way that it receives light rays emitted by the VCSEL laser 1010. Because of this, the light rays emitted by the laser 1010 in the direction of the photodiode 1030 are converted into electric current by the photodiode for detecting a possible malfunction of the VCSEL laser 1010 and/or regulating its average power.

During a step 1111, an optical fiber is inserted in a fiber carrier and these two elements are secured.

During a step 1112 (FIG. 20B), the optical fiber is cleaved, so that the part of the fiber projecting from the fiber carrier has a length L. The cleaving may be carried out at an angle with respect to the axis of the optical fiber, to limit the secondary reflections.

During a step 1113, a fiber fixed in a fiber carrier is inserted, in at least one hole.

During a step 1114, the optical fiber carrier is fixed to the main substrate, for example by gluing or brazing, facing a laser, said fiber carrier at the end of the assembly process touching the main substrate surface opposite the mounting pad of the host substrate on the main substrate.

For fixing the optical fiber, you use, for example, an adhesive with an optical index close to that of the optical fiber which, by capillary action, fills the space between the optical fiber and the hole.

During an optional step 1115, the gap between the active surface of the optoelectronic component and the end of the optical fiber is filled with a transparent material whose optical index is close to that of the optical fiber.

During the operation of the VCSEL laser, step 1116, the candlepower emitted by this laser is measured with the photodiode placed on the main substrate 1005, and this power is controlled, step 1117, by regulation, according to techniques known per se.

FIG. 21 shows a variant of the invention adapted the case where the respective power of several VCSEL lasers 1010, each integrated on a host substrate 1007, must be monitored and regulated. Thus, photodiodes 1030 comprising as many distinct photosensitive areas as there are VCSEL lasers 1010 are mounted, in the same way as above.

FIG. 21 shows that this invention, the characteristics of which are described above for one single laser 1010, may easily be utilized in what are known as parallel optics applications, in which several vertical emitting lasers 1010 need to be aligned simultaneously to a band of optical fibers 1025, typically numbering 4, 8 or 12.

To this end, the band of optical fibers 1025 is placed in a multi-fiber rod or fiber carrier 1075 or in a block of what are known as “V-grooves” and a collective cleaving of the optical fibers 1025 is carried out such that each optical fiber 1025 projects from the fiber carrier by a defined length L. With regard to the main substrate 1055, this is pierced by a number of holes 1050, the number of which corresponds to the number of lasers 1010 to be coupled to the optical fibers 1025.

In order to simultaneously monitor several VCSEL lasers 1010 packaged in one single optoelectronic housing, for what is known as a parallel optics application, the operations described in FIGS. 20A and 20B are realized for each VCSEL laser 1010, these VCSEL lasers 1010 then being assembled on the common main substrate 1055, and a monitoring and regulation photodiode 1030 is positioned for each laser 1010, as indicated above.

This problem can also be handled collectively, not by using discrete or separated VCSEL substrates, but by using a host substrate bearing several VCSELs 1010 in a line or in a matrix. The processes mentioned above are collective and can thus be applied simultaneously on all the lasers 1010.

Eighth to Fifteenth Aspects.

FIG. 22 shows a substrate 1203 bearing, on a first surface (the upper surface in FIG. 22), a first layer of dielectric material 1201, a conductive line 1204 and a second layer of dielectric material 1202 on which a weld 1205 attaches a housing 1200. A piercing 1206 is formed from the second surface of the substrate (the lower surface in FIG. 22) opposite the first surface up to the conductive line 1205, with respect to the interior of the housing 1200.

The housing 1200 is, for example, silicon.

The piercing 1206 enables electronic components outside the housing 1200 to be connected to electronic components 1210 located inside the housing 1200, according to known techniques. The piercing 1206 is realized, for preference, before the packaging by the traditional masking techniques (resin application, photolithography and opening by wet or dry etching). It is then filled with metal to enable the electrical connection between the conductive line 1204 and the outside of the housing 1200. It is noted that the method of realizing the piercing is performed in two steps (the metal conductive line 1205 ensuring hermeticity with regard to the exterior, a hole is realized then it is filled with metal, the hole not needing to be perfectly hermetic after being filled by metal).

The realization of the electrical feed-through shown in FIG. 22 obviates having the signals carried by the conductive line 1204 passing close to the housing 1200 and, in the case where the latter is a conductive material, these signals experiencing interference due to this closeness (“ground plane” effect).

The role of the first layer of dielectric material 1201 is to isolate all the inbound-outbound conductive lines of the electronic components 1210 from the substrate. The substrate 1203 itself may be complex and comprise the stacking of conduction and/or interconnection layers for various integrated components. The practical example describing this type of complex substrate is a silicon substrate integrating various electronic functions.

It is noted that the silicon substrate is generally selected with a high resistivity. In certain applications (not shown) for which the electrical insulation must be greater, the contacts are insulated by trenches or dielectric material is deposited on the edges of the hole.

The inbound-outbound conductive lines 1204 are then realized on this first layer of dielectric material 1201 by the conventional techniques of evaporation deposition.

An optional second layer of dielectric material 1202 is then deposited on these conduction lines 1204, which allows these lines to be mechanically strengthened. Hermeticity is ensured by the Indium weld (brazing) 1205. The differences in level introduced by the deposition of the metal comprising the conductive lines in the second layer of dielectric material may, where necessary, be overcome by simple planarization of the second dielectric by conventional wafer polishing techniques.

In the embodiment shown, the housing 1200 is thus soldered on the second layer of dielectric material 1202, in a manner known per se.

Thanks to this first aspect of this invention, even when the housing packaging the electronic components 1210 borne by the substrate 1203 is metallic, the ground plane effect, which might interfere with the signals carried by the conductive line 1204, especially if these are microwave signals, is avoided, because the path of these signals stays far from the edge of the housing 1200.

In the embodiment shown in FIGS. 23 thru 26, the deposition of a cylinder or bead mount 1401 of fusible material is carried out (FIG. 23). This deposition is known in the flip-chip type of technology, but, instead of being applied to electronic components, it is applied to connecting a housing on the substrate and, instead of applying it to the transmission of electrical signals, it is applied to the housing's mechanical hold on the substrate.

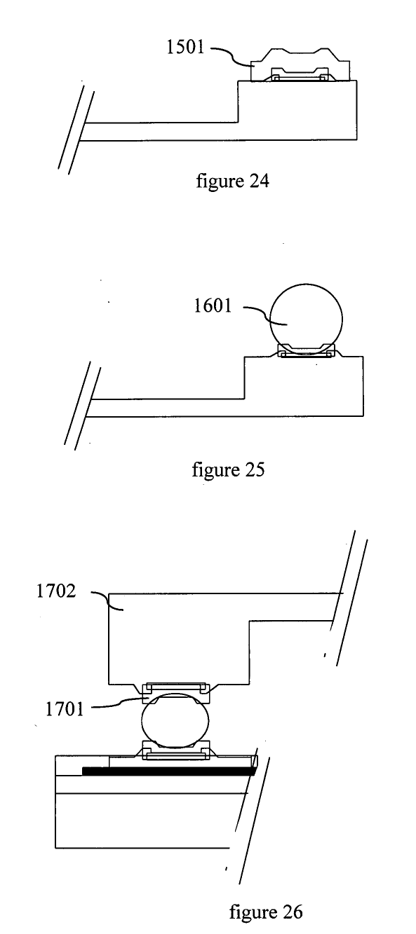

Then the deposition of fusible material 1501 is carried out, as shown in FIG. 24. This deposition is carried out at low temperature by evaporation of the indium metal.

Then the fusible material is melted and it spontaneously takes the form of a bead 1601 or a cylinder, depending on the shape of the mount 1401, under the effect of surface tension forces, as shown in FIG. 25.

The principle of evaporation deposition of a metal or any other form of deposition (electrolytic, for example) is well known to the expert. Thus, via the steps that are standard in microelectroncs of resin deposition, lithography, insulation, an open area is defined whose dimensions are controlled to better than a micron and where the deposition of the indium metal or any other metal may be carried out. Once the metal has been deposited, the resin is eliminated and this metal may be re-melted to form a cylindrical seal (FIG. 26).

The indium metal taken as an example may be replaced by indium-based alloys, such as indium-tin (InSn). In the case of indium, the formation of the continuous seal by increasing the temperature in order to turn the indium liquid is undertaken between 160° C. and 175° C. Hermeticity is then obtained by re-fusing the continuous seal on the base of the housing, itself exhibiting a suitable metallization.

Finally, the housing 1702, equipped with a cylinder or bead mount 1701 identical to that of the substrate 1203, is placed on these beads, abutting, as shown in FIG. 26.

In the embodiment shown in FIGS. 27 and 28, starting from the state of the substrate obtained at the end of step 1303, a seal in a ductile material 1801 is deposited facing the defined position of the housing 1802 packaging the electronic components borne by the substrate and a knife shape 1803 is provided on the edge of the housing, a shape intended to be sunk into the seal thus constituted.

The shape of the edges of the housing 1802 is such that its thickness, at its end, is less than half the average thickness of the housing 1802. In a preferential embodiment, this shape 1803 is a prismatic shape with a basically triangular cross-section whose end angle is acute, for example about 60 degrees or 1 radian.

On the housing part a conical-type seal surface has thus been realized, with an acute or slightly rounded surface allowing the sectioning of the seal part to be avoided, in certain cases. The total thickness of the seal in this case may be greater than 10 μm. In a general way, the surface of the housing should not exceed the thickness of metal.

Under the effect of mechanical forces exercised either by a negative pressure inside the housing 1802 (for example a residual pressure of less than 10⁻⁴ Torr), or by methods of maintaining position (not shown), the edges of the housing 1802 remain sunk in the seal 1801 and there is no risk of them moving parallel to the plane of the substrate 1800.

It is observed, on the first line of FIG. 28, that before the assembly of the housing 1802 on the substrate 1800, the substrate 1800 bears each electronic component 1805 to be packaged and the seal 1801, all round component 1805. In addition, the housing 1802 is constituted so that its edges present the knife shape mentioned above.

Then, as shown in the second line of FIG. 28, on the left, the housing 1802 is positioned on the substrate 1800 by pressing the knife-shaped edges of the housing 1802 into the seal 1801 so as to enclose the electronic components to be packaged, between the housing 1802 and the substrate 1800. In the example represented in top view, in the second line, to the right of FIG. 28, two electronic components 1901 and 1902 are packaged and they have six conductive lines, in total, for communicating with the outside of the housing 1802.

FIG. 29 shows a packaging of electronic components identical to that shown in FIG. 28, except for the knife 1901, which is borne by the substrate 1900, and the seal 1903, which is borne by the edge of the housing 1902.

The embodiments shown in FIGS. 28 and 29 concern the electronic components fields encompassing all standard memory components, analog or logic circuits, power circuits, for example. The components are, for example, mounted by “flip-chip” techniques, the interconnections then being provided by lines realized on a silicon platform for example, or simply glued on the surface and interconnected by wires to the transmission wires previously mentioned. All the outbound lines may also be realized as described above with respect to FIG. 22.

As shown in FIG. 30, when one of the packaged electronic components is an optoelectronic component 2002, a window 2003 of material at least partially transparent in the spectral band of light utilized by the component in question may be provided on the substrate 2000.

In the embodiment shown in FIG. 30, an optical fiber 2006 is borne by a rod 2007 presenting, on its surface facing the substrate 2000, a knife shape 2004 similar to the knife shape of the edges of the housing 2001, which is sunk into a seal 2005 formed on the substrate 2000.

In this case, the substrate is transparent to the wavelengths considered, facing the end of the optical fiber. The substrate is, for example, in silicon, quartz or Gallium Arsenide.

In the embodiment shown in FIG. 31, the housing 2100 is realized in material transparent in the spectral band of light utilized by the optoelectronic component 2101. For example, the housing 2100 is realized in quartz, silicon, or Gallium Arsenide). For preference it comprises a window 2102 with a thickness of less than 100 μm.

FIG. 32 shows that a bead 2200 of fusible material, for example Indium, is positioned at the exit of a gas pump line 2201 present in the housing 2202. The bead 2200 thus produces a micro-gate. When the vacuum has been at least partially produced in the housing 2202, the bead 2200 is heated to its fusing point. By capillary action, it then descends into the pipe 2201 and solidifies there, with the result that this pipe 2201 is plugged. In a variant, during the heating of the bead 2200, the pressure outside the housing 2202 is raised so that the bead 2200, in fusion, is drawn into the inside of the pipe 2201. The housing is thus hermetically closed and kept in place by the negative pressure.

The examples of applications of this invention are numerous and concern many fields of applications, such as microelectronics, MEMS (acronym for MEchanical Mobile Semiconductors) technologies, optics, optoelectronics, detection systems, sensor systems etc.

For preference, the packaging of optoelectronic or electronic components is realized in a collective way on a single substrate which is then cut to separate the housing-substrate assemblies.

1. An assembly comprising an electronic component wherein said component is connected by microbeads to at least one heat sink, said beads being connected to electrically conductive lines on said electronic component and to electrically conductive lines on at least one heat sink, said beads carrying electrical signals between the electronic component and each heat sink bearing said electrically conductive lines and the heat from the electronic component to each heat sink, via heat conduction.

2. An assembly according to claim 1, comprising a coating that coats the beads, at least one part of the electronic component and at least one part of a heat sink, said coating being an element that is a heat conductor and also an electrical insulator.

3. An assembly according to claim 1, wherein at least one heat sink is integrated into a housing of the electronic component.

4. An assembly according to claim 1, wherein at least one heat sink also makes up a part of a housing of the electronic component.

5. An assembly according to claim 1, wherein at least one heat sink integrates a generator of current and modulation and/or electronics, allowing the electronic component to operate and/or be monitored.

6. An assembly according to claim 1, wherein one heat sink is created using a semiconductive material and a second heat sink is a mounted semiconductor or metallic element.

7. An assembly according to claim 1, wherein at least one heat sink comprises a hole facing said electronic component and said component is an optoelectronic component.

8. An assembly according to claim 7, comprising an optical fiber in said hole.

9. A process for assembling an electronic component comprises comprising the steps of:
preparing at least one heat sink for which, over at least one said heat sink, electrically conducive lines are linked to mounts for beads; and
connecting, by microbeads, said electronic component to at least one heat sink, said beads being linked to electrically conductive lines on said electronic component and to mounts for beads on the heat sink, said beads carrying electrical signals between the electronic component, and each heat sink bearing said electrically conductive lines and the heat from the electronic component to each heat sink, via heat conduction.

10. A process according to claim 9, comprising a step of closing a housing including at least one said heat sink.

11. An assembly according to claim 2, wherein at least one heat sink is integrated into a housing of the electronic component.

12. An assembly according to claim 2, wherein at least one heat sink also makes up a part of a housing of the electronic component.

13. An assembly according to claim 2, wherein at least one heat sink integrates a generator of current and modulation and/or electronics, allowing the electronic component to operate and/or be monitored.

14. An assembly according to claim 2, wherein one heat sink is created using a semiconductive material and a second heat sink is a mounted semiconductor or metallic element.

15. An assembly according to claim 2, wherein at least one heat sink comprises a hole facing said electronic component and said component is an optoelectronic component.

16. An assembly according to claim 3, wherein at least one heat sink also makes up a part of a housing of the electronic component.

17. An assembly according to claim 3, wherein at least one heat sink integrates a generator of current and modulation and/or electronics, allowing the electronic component to operate and/or be monitored.

18. An assembly according to claim 3, wherein one heat sink is created using a semiconductive material and a second heat sink is a mounted semiconductor or metallic element.

19. An assembly according to claim 3, wherein at least one heat sink comprises a hole facing said electronic component and said component is an optoelectronic component.

20. An assembly according to claim 4, wherein at least one heat sink comprises a hole facing said electronic component and said component is an optoelectronic component.
